(19) United States
(12) Patent Application Publication
(10) Pub. No.: US 2021/0305442 A1
(43) Pub. Date: Sep. 30, 2021

(54) DILUTE NITRIDE OPTOELECTRONIC ABSORPTION DEVICES HAVING GRADED OR STEPPED INTERFACE REGIONS

(71) Applicant: Array Photonics, Inc., Tempe, AZ (US)

(72) Inventors: Ferran SUAREZ, Chandler, AZ (US); Aymeric Maros, San Francisco, CA (US)

(21) Appl. No.: 17/202,186

(22) Filed: Mar. 15, 2021

Related U.S. Application Data
(60) Provisional application No. 63/000,628, filed on Mar. 27, 2020.

(51) Int. Cl. H01L 31/0304; H01L 31/107

(52) U.S. Cl. CPC H01L 31/03048; H01L 31/1075

(57) ABSTRACT

Semiconductor optoelectronic devices having a dilute nitride active region and at least one graded or stepped interface layer between the dilute nitride active region and an adjacent higher bandgap semiconductor layer, such as a cladding layer are disclosed. In particular, the semiconductor devices have a dilute nitride active region with at least one bandgap within a range from 0.7 eV and 1.4 eV. Photodetectors comprising a dilute nitride active region with at least one graded or stepped interface layer have a higher carrier collection efficiency and a reduced dark current when compared to photodetectors comprising a dilute nitride active region without a graded or stepped interface layer.

### CROSS-REFERENCE TO RELATED APPLICATION

This application claims the benefit of U.S. Provisional Application No. 63/000,628, filed Mar. 27, 2020, the contents of which are incorporated herein by reference in the entirety for all purposes.

### FIELD

The disclosure relates to semiconductor optical absorption devices having a dilute nitride active region and graded or stepped interfaces between the dilute nitride active region and the adjacent higher bandgap cladding layers.

### BACKGROUND

Dilute nitride compound semiconductor materials, such as GaInNAs, GaNAsSb, GaInNAsSb, GaInNAsBi, GaNAsSbBi, GaNAsBi, and GaInNAsSbBi can be engineered to have bandgaps between about 0.7 eV and 1.4 eV, while remaining closely lattice matched to substrates such as GaAs and Ge. The tunability of this material system has made it of interest for a variety of optoelectronic devices and applications, including semiconductor optoelectronic absorption devices, such as photodetectors, solar cells, power converters, and semiconductor lasers. The dilute nitride material system allows device operation in the wavelength range between about 0.9 μm and 1.8 μm, with applications including power generation, fiber optic communications, free-space communications, sensing and imaging. For example, high efficiency multijunction solar cells have been demonstrated that include a dilute nitride optical absorber with a bandgap between about 0.9 eV and 1.1 eV. Narrower bandgap dilute nitride materials have also been proposed to replace low-bandgap (0.7 eV) Ge junctions in multijunction solar cells, and as an alternative to InGaAs/InP based photodiodes. Laser operation at wavelengths up to about 1.5 μm has also been demonstrated. For optoelectronic devices such as lasers and photodetectors operating at eye-safe wavelengths between about 1.3 μm and 1.55 μm, InGaAs on InP materials currently dominate the market. However, the material system has several limitations, including the high cost of InP substrates, low yields due to the fragility of the InP substrates, and limited InP wafer diameter (and associated quality issues at larger diameters). From a manufacturing perspective and also from an economic perspective, gallium arsenide (GaAs) represents a better substrate choice.

With respect to photodetectors, devices that can be produced include high-speed photodetectors for telecommunications applications, and arrays of photodetectors that can be used as sensors and imagers for military, biomedical, industrial, environmental and scientific applications. In such applications, photodetectors with high responsivity, low dark current and low noise are desirable, requiring dilute nitride materials with low background carrier concentrations and low levels of defects. Extending the wavelength range of operation of dilute nitride materials typically requires a higher nitrogen content in the dilute nitride alloy. This can lead to higher background carrier concentrations and higher levels of defects, which can decrease the efficiency of devices and can also generate noise in photodetectors and associated losses in solar cells. Furthermore, increasing nitrogen content increases the height of the barriers between the dilute nitride layers and adjacent cladding layers. This can lead to carrier trapping which can decrease current collection efficiency of devices, as well as limit the speed of photodetectors.

Thus, to take advantage of the manufacturing scalability and cost advantages of GaAs substrates, there is continued interest in developing long-wavelength materials on GaAs that have improved optoelectronic performance.

### SUMMARY

According to the present invention, a compound semiconductor optoelectronic structure comprises: a substrate having a substrate surface; a first doped region overlying the substrate surface, wherein the first doped region is characterized by a first doped region bandgap; an active region overlying the first doped region, wherein the active region comprises a dilute nitride material, wherein the dilute nitride material is characterized by a dilute nitride material bandgap; a second doped region overlying the active region, wherein the first doped region is characterized by a second doped region bandgap; and a first interface region adjacent to the active region and to the first doped region; or a second interface region adjacent the active region and the second doped region; or a first interface region adjacent to the active region and to the first doped region and a second interface region adjacent the active region and the second doped region; wherein the first interface region is characterized by a first interface region bandgap, and the first interface region bandgap is intermediate between the dilute nitride material bandgap and the first doped region bandgap; and wherein the second interface region is characterized by a second interface region bandgap, and the second interface region bandgap is intermediate between the dilute nitride material bandgap and the second doped region bandgap.

### BRIEF DESCRIPTION OF THE DRAWINGS

The drawings described herein are for illustration purposes only. The drawings are not intended to limit the scope of the present disclosure.

FIG. 1 shows a side view of an example of a semiconductor optoelectronic structure according to the present invention.

FIG. 2 shows a side view of another example of a semiconductor optoelectronic structure according to the present invention.

FIG. 3 shows a side view of another example of a semiconductor optoelectronic structure according to the present invention.

FIG. 4 shows a side view of an example of a photodetector according to the present invention.

FIGS. 5A and 5B are diagrams showing hybrid integration of a detector array chip with an array of readout circuits on a readout integrated circuit (ROIC) chip.

FIG. 6 shows a schematic cross-section of a dilute nitride active region according to the present invention.

FIG. 7 shows a band edge alignment for a dilute nitride active region according to the present invention.

FIG. 8A shows a band edge alignment for a dilute nitride active region according to the present invention.

FIG. 8B shows a band edge alignment for a dilute nitride active region according to an the present invention.

FIG. 8C shows a band edge alignment for a dilute nitride active region according the present invention.

FIG. 9 shows a schematic cross-section of a four-junction multijunction solar cell with a dilute nitride subcell according to the present invention.

FIG. 10 shows a schematic cross-section of a five-junction multijunction solar cell with two dilute nitride subcells according to the present invention.

FIGS. 11A and 11B are band edge alignment diagrams for prior art dilute nitride-based heterostructures.

FIGS. 12A and 12B are examples band edge alignment diagrams for dilute nitride based heterostructures with graded interfaces according to the present invention.

FIG. 13 is a band edge alignment diagrams for a dilute nitride based heterostructure with graded interfaces according to an embodiment of the invention.

FIG. 14 shows schematic cross-sections of graded interface layers according to the present the invention.

FIGS. 15A-15C shows side views of examples of photodetectors having graded interface layers according to the present invention.

FIG. 16A shows a schematic of a device having III-V semiconductor layers grown on a GaAs substrate.

FIG. 16B shows a schematic of a device having III-V semiconductor layers grown on a Ge substrate.

FIG. 17A shows a semiconductor device having a lattice-engineered SiGe buffer layer overlying a silicon substrate.

FIG. 17B shows a semiconductor device having a lattice-engineered SiGeSn buffer layer overlying a silicon substrate.

FIG. 18 shows a semiconductor device having a lattice-engineered rare earth-containing buffer layer overlying a silicon substrate.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized, and structural, logical, and electrical changes may be made without departing from the scope of the invention. The various embodiments disclosed herein are not necessarily mutually exclusive, as some disclosed embodiments may be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

The term “lattice-matched” as used herein means that the two referenced materials have the same lattice constant or a lattice constant differing by less than +/−0.2%. For example, GaAs and AlAs are lattice-matched, having lattice constants differing by 0.12%.

The term “pseudomorphically strained” as used herein means that layers made of different materials with a lattice constant difference up to +/−2% can be grown on top of a lattice-matched or strained layer without generating misfit dislocations. The lattice parameters can differ, for example, by up to +/−1%, by up to +/−0.5%, or by up to +/−0.2%.

The term “active layer” as used herein, means a continuous region of a material (e.g., an alloy) that can be undoped, uniformly doped, or non-uniformly doped and that can have a uniform or a non-uniform composition across the thickness of the layer.

The term “active region” refers to a semiconductor region capable of processing light, which includes, for example, absorbing light, emitting light, and/or modulating light. An active region can comprise a single material layer or multiple material layers such as multiple active layers.

A “bandgap that varies continuously” refers to a bandgap that varies across the thickness of a region or layer and is not constant over a portion of the thickness.

A “bandgap that varies discontinuously” refers to a bandgap that varies across the thickness of a region or layer where there is a bandgap discontinuity or bandgap step.

A “bandgap that varies linearly” refers to a bandgap that varies across the thickness of a region or layer such that the bandgap=a+b×x, where a is a first bandgap energy, b is a constant associated with a bandgap change and x is a position with respect to the thickness of the region or layer.

A “bandgap that varies quadratically” refers to a bandgap that varies across the thickness of a region or layer such that the bandgap=a+b×x², where a is a first bandgap energy, b is a constant associated with a bandgap change and x is a position with respect to the thickness of the region or layer.

A “bandgap that varies polynomially”, refers to a bandgap that varies across the thickness of a region or layer such that the bandgap=a+b×xⁿ, where a is a first bandgap energy, b is a constant associated with a bandgap change, n is a positive integer and x is a position with respect to the thickness of the region or layer.

A “bandgap that varies as a square root” refers to a bandgap that varies across the thickness of a region or layer such that the bandgap=a+b×x^{1/2}, where a is a first bandgap energy, b is a constant associated with a bandgap change and x is a position with respect to the thickness of the region or layer.

A “stepped bandgap” or a “discontinuous bandgap” refers to a bandgap that has at least one bandgap step or discontinuity across the thickness of a region or a layer such that the bandgap=a+b×H(x-x₀), where a is a first bandgap energy, b is a constant associated with a bandgap change, H(x-x₀) is a step function such as a Heaviside step function, x₀ is a reference position within the thickness of the region or layer, and x is a position with respect to the reference position within the thickness of the region or layer.

A “bandgap that varies exponentially” refers to a bandgap that varies across the thickness of a region or layer such that the bandgap=a+b×e^{x}, where a is a first bandgap energy, b is a constant associated with a bandgap change and x is a position with respect to the thickness of the region or layer.

A “constant doping profile’ refers to a doping profile that is constant across the thickness of a region or layer.

A “continuous doping profile” refers to a doping profile that changes continuously across the thickness of a region or layer.

A “discontinuous doping profile” refers to a doping profile that is continuous in a portion of a region or layer and is constant in another portion of the region or layer.

The “diameter” of a device refers to a size of the device at the light-receiving surface. For example, referring to FIG. 4, the diameter of the device is the region between contacts 412 and covered by antireflection coating 416.

The “short wavelength cut-off” refers to the shortest wavelength of light that is absorbed in an active region and generates an electrical output, such as a current and/or a voltage.

The term “full width half maximum” (FWHM) refers to the wavelength range of a spectral response at which the amplitude is 50% the maximum amplitude.

“Orthogonal to the substrate surface” means perpendicular to the growth surface and in the thickness of the layer. For example, an active region that has a bandgap that varies orthogonal to the substrate surface has a bandgap that varies in the thickness direction of the active layer.

“Photoluminescence” can be determined by measuring the optical emission from a material or device that is subject to photon excitation in the material by an external light source, such as a laser. Laser light absorbed within the material or device causes photons to be emitted that are characteristic of the properties of the absorbing material. The responsivity can be determined by illuminating a device with a light source with known output light characteristics, such as a broad-band halogen lamp, with light monochromatized into narrow wavelength bands (such as 10 nm or 5 nm or 1 nm) and measuring the electrical current generated by the device.

The term “bandgap” as used herein is the energy difference between the conduction and valence bands of a material.

The term “responsivity” of a material as used herein is the ratio of the generated photocurrent to the incident light power at a given wavelength. The responsivity can be determined using a broad-band halogen lamp, with light monochromatized with 10 nm wavelength band.

“Room temperature” refers to a temperature from 23° C. to 25° C.

“Adjacent” as used herein means adjoining or against. For example, a first layer is adjacent a second layer such that there are no intentional intervening layers between the first and second layers.

“Region” as used herein refers to a semiconductor region having a specific function. A region can comprise one layer or more than one layers. Different layers forming a region can have, for example, different thicknesses, material compositions, different doping profiles, and/or different bandgaps.

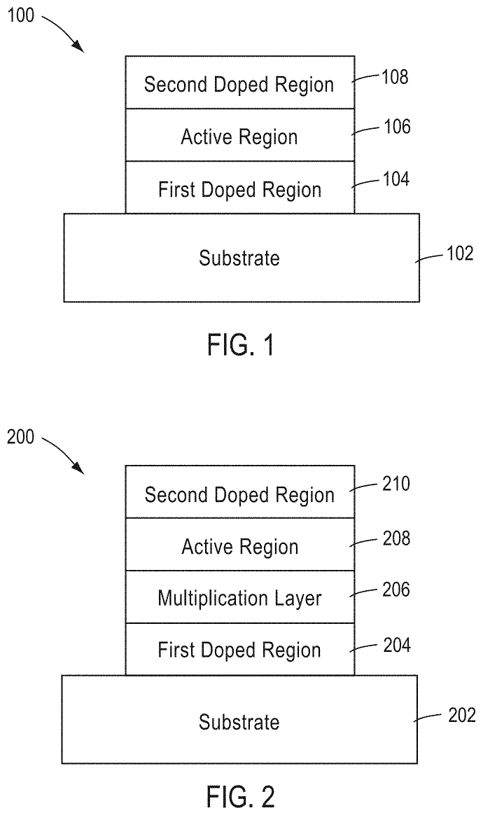

FIG. 1 shows a side view of an example of a semiconductor optoelectronic structure 100 according to the present invention. Device 100 comprises a substrate 102, a first doped region 104, an active region 106, and a second doped region 108. For simplicity, each region is shown as a single layer. However, it will be understood that each region can include one or more layers with differing compositions, thicknesses, and doping levels to provide an appropriate optical and/or electrical functionality, and to improve interface quality, electron transport, hole transport and/or other optoelectronic properties.

Substrate 102 can have a lattice constant that matches or nearly matches the lattice constant of GaAs or Ge. The substrate can be GaAs. Substrate 102 may be doped p-type, or n-type, or may be a semi-insulating (SI) substrate. The thickness of substrate 102 can be chosen to be any suitable thickness. Substrate 102 can include one or more layers, for example, the substrate can include a Si layer having an overlying SiGeSn buffer layer, a rare-earth containing layer, or a graded SiGe layer that is engineered to have a lattice constant that matches or nearly matches the lattice constant of GaAs or Ge.

First doped region 104 can have a doping of one type and the second doped region 108 can have a doping of the opposite type. If first doped region 104 is doped n-type, second doped region 108 is doped p-type. Conversely, if first doped region 104 is doped p-type, second doped region 108 is doped n-type. Examples of p-type dopants include C and Be. Examples of n-type dopants include Si and Te. Doped regions 104 and 108 are chosen to have a composition that is lattice-matched or pseudomorphically strained with respect to the substrate. The doped regions can comprise any suitable III-V material, such as GaAs, AlGaAs, GaInAs, (Al)GaInP, (Al)GaInPAs, GaInNAs, and/or GaInNAsSb. The bandgap of the doped regions can independently be selected to be larger than the bandgap of active region 106. Doping levels of each of the doped regions can independently be within a range, for example, from 1×10¹⁵ cm⁻³ to 2×10¹⁹ cm⁻³, from 1×10¹⁶ cm⁻³ to 2×10¹⁸ cm⁻³, 2×10¹⁶ cm⁻³ to 1×10¹⁸ cm⁻³, or from 1×10¹⁷ cm⁻³ to 1×10¹⁹ cm⁻³. Doping levels may be constant within a doped region, and/or the doping profile may be graded within a doped region, for example, the doping level can increase from a minimum value to a maximum value as a function of the distance from the interface between the first doped region 104 and the active region 106 and/or from the interface between the second doped region 108 and the active region 106. Doped regions 104 and 108 can independently have a thickness within a range, for example, from 50 nm to 3 μm, from 100 nm to 2.5 μm, from 200 nm to 2 μm, or from 500 nm to 1.5 μm.

Active region 106 can be lattice-matched or pseudomorphically strained with respect to the substrate and/or to the doped regions. The maximum bandgap of active region 106 can independently be less than that of the doped regions 104 and 108. For example, the maximum bandgap of active region 106 can be at least 25 meV less than the bandgap of each of doped regions 104 and 108, at least 100 meV less, at least 200 meV less, at least 400 meV less, at least 600 meV less, at least 800 meV less, or at least 1,000 meV less than the bandgap of each of doped regions 104 and 108. The bandgap of each of doped region 104 and 108 can be, for example, from 25 meV to 1,000 meV greater than the maximum bandgap of the active region 106, from 50 meV to 800 meV, from 100 meV to 600 meV, or from 200 meV to 500 meV greater than the bandgap of the active region 106. The bandgap of each of doped regions 104 and 108 can be, for example, about 1. 4 eV for GaAs materials or at least 1.4 for materials such as InGaP, InGaAlP and InGaAlPAs.

Active region 106 can comprise one or more layers capable of processing light over a desired wavelength range. Processing light includes, for example, emitting light, receiving light, sensing light, and/or modulating light.

Active region 106 can include a dilute nitride material. A dilute nitride material can include GaInNAs, GaNAsSb, GaInNAsSb, GaInNAsBi, GaNAsSbBi, GaNAsBi, and/or GaInNAsSbBi. In some embodiments, the dilute nitride material can be Ga₁₋ₓInₓN_{y}As_{1-y-z}Sb_{z}, where x, y and z can be 0≤x≤0.4, 0≤y≤0.07 and 0≤z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z} Sb_{z}, where, for example, 0.12≤x≤0.24, 0.03≤y≤0.07 and 0.005≤z≤0.04; 0.13≤x≤0.2, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.024. Active region 106 can have a bandgap within a range from 0.7 eV and 1.3 eV such that the active region can absorb or emit light at wavelengths up to 1.8 μm. Bismuth (Bi) may be added as a surfactant during growth of the dilute nitride material, improving material quality (such as defect density), and the device performance. The thickness of active region 106 can be within a range, for example, from 0.2 μm to 10 μm. The thickness of active region 106 can be within a range, for example, from 0.5 μm to 5 μm. The thickness of active region 106 can be within a range, for example, from 1 μm to 4 μm, from 1 μm to 3 μm, or from 1 μm to 2 μm. Active region 106 can be compressively strained with respect to the substrate 102. Strain can improve device performance. For a photodetector, the parameters most relevant to device performance include the dark current, operating speed, noise, and responsivity.

In FIG. 1, active region 106 is shown as a single active layer, but it will be understood that active region 106 can include more than one active layers with each of the active layers comprising a dilute nitride material, and with each of the active layers independently having a bandgap within a range from 0.7 eV and 1.4 eV. In some examples, active region 106 can include a single active layer with different portions of the active region having different doping profiles. Examples of doping profiles for dilute nitride optical absorber materials are described in U.S. Application Publication No. 2016/0118526, which is incorporated by reference in its entirety.

Active region 106 and doped regions 104 and 108 can form a p-i-n or an n-i-p junction. This junction provides the basic structure for operation of a device such as a photodetector or a light-emitting diode. For photodetectors, p-i-n epitaxial structures can have low background doping in the intrinsic region (active region) of the devices which are typically operated at 0 V or at very low bias. Therefore, the active region 106 may not be deliberately doped. The active region can be intrinsic or can be unintentionally doped. Unintentionally doped semiconductors do not have dopants intentionally added but can include a nonzero concentration of impurities that act as dopants. The background carrier concentration of the intrinsic or unintentionally doped active region, which is equivalent to the dopant concentration, can be, for example, less than 1×10¹⁶ cm⁻³ (measured at room temperature (25° C.), less than 5×10¹⁵ cm⁻³, or less than 1×10¹⁵ cm⁻³. The minority carrier lifetime within the active region can be, for example, greater than 1 ns, greater than 1.5 ns, or greater 2 ns. The minority carrier lifetime can be affected by defects within the semiconductor that contribute to the background carrier concentration, as well as other defect types that can act as recombination centers but do not contribute carriers.

FIG. 2 shows a semiconductor optoelectronic structure 200 with a p-i-n diode and a multiplication layer 206. Structure 200 is similar to structure 100, but also includes a multiplication layer. The purpose of the multiplication layer 206 is to amplify the photocurrent generated by the active region 208 of a photodetector device. Optoelectronic structure 200 can provide an avalanche photodiode (APD). An APD introduces an additional p-n junction into the structure, as well as introduces an additional thickness. This allows a higher reverse bias voltage to be applied to the structure, which results in carrier multiplication by the avalanche process.

Substrate 202 can have a lattice constant that matches or nearly matches the lattice constant of GaAs or Ge. The substrate can be GaAs. Substrate 202 may be doped p-type, or n-type, or may be a semi-insulating (SI) substrate. The thickness of substrate 202 can be chosen to be any suitable thickness. Substrate 202 can include one or more layers, for example, a Si layer having an overlying SiGeSn buffer layer that is engineered to have a lattice constant that matches or nearly matches the lattice constant of GaAs or Ge. This can mean the substrate has a lattice parameter different than that of GaAs or Ge by less than or equal to 3%, less than 1%, or less than 0.5% that of GaAs or Ge.

First doped region 204 can have a doping of one type and the second doped region 210 can have a doping of the opposite type. If first doped region 204 is doped n-type, second doped region 210 is doped p-type. Conversely, if first doped region 204 is doped p-type, second doped region 210 is doped n-type. Examples of p-type dopants include C and Be. Examples of n-type dopants include Si and Te. Doped regions 204 and 210 can independently be chosen to have a composition that is lattice-matched or pseudomorphically strained with respect to the substrate. The doped regions can comprise any suitable III-V material, such as GaAs, AlGaAs, GaInAs, (Al)GaInP, (Al)GaInPAs, AlInP, GaInNAs, and GaInNAsSb. The bandgap of the doped regions can be independently selected to be larger than the bandgap of active region 208. Doping levels can be within a range, for example, from 1×10¹⁵ cm⁻³ to 2×10¹⁹ cm⁻³, from 1×10¹⁶ cm⁻³ to 2×10¹⁸ cm⁻³, 2×10¹⁶ cm⁻³ to 1×10¹⁸ cm⁻³, or from 1×10¹⁷ cm⁻³ to 1×10¹⁹ cm⁻³. Doping levels may be constant within a layer and/or the doping profile may be graded, for example, the doping level can increase from a minimum value to a maximum value as a function of the distance from the interface between the second doped region 210 and the active region 208 or from the interface between the first doped region 204 and the active region 206. Doped regions 204 and 210 can have a thickness, for example, within a range from 50 nm and 3 μm, from 100 nm to 2.5 μm, from 200 nm to 2 μm, or from 500 nm to 1.5 μm.

Active region 208 can be lattice-matched or pseudomorphically strained with respect to the substrate and/or to the doped regions. The maximum bandgap of active region 208 can be lower than that of the doped regions 204 and 210. Active region 208 can comprise one or more layers capable of processing light over a desired wavelength range.

Active region 208 can include a dilute nitride material. A dilute nitride material can include GaInNAs, GaNAsSb, GaInNAsSb, GaInNAsBi, GaNAsSbBi, GaNAsBi, and/or GaInNAsSbBi. In some embodiments, the dilute nitride material can be Ga₁₋ₓInₓN_{y}As_{1-y-z} Sb_{z}, where x, y and z can be 0≤x≤0.4, 0≤y≤0.07 and 0≤z≤0.04, respectively. X, y and z can be 0.01≤x≤0.4, 0.02≤y≤0.07 and 0.001≤z≤0.04, respectively. In other embodiments, dilute nitride materials can have compositions as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z} Sb_{z}, where, for example, 0.12≤x≤0.24, 0.03≤y≤0.07 and 0.005≤z≤0.04; 0.13≤x≤0.20, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.04. Active region 208 can have a bandgap within a range from 0.7 eV to 1.3 eV such that the active region can absorb or emit light at wavelengths up to 1.8 μm. Bismuth (Bi) may be added as a surfactant during growth of the dilute nitride, improving material quality (such as defect density), and the device performance. The thickness of active region 208 can be within a range, for example, from 0.2 μm to 10 μm, from 0.5 μm to 5 μm, or from 1 μm to 4 μm. Active region 208 can be compressively strained with respect to the substrate 202. Strain can also improve device performance. For a photodetector, the device performance of most relevance includes the dark current, operating speed, noise and responsivity.

In FIG. 2, active region 208 is shown as a single layer, but it will be understood that active region 208 can include more than one active layer and each active layer can comprise a dilute nitride material which can independently have a bandgap within a range from 0.7 eV and 1.4 eV, as will be described later. In some examples, active region 208 can include regions with different doping profiles. Examples of doping profiles for dilute nitride optical absorber materials are described in U.S. Application Publication No. 2016/0118526, which is incorporated by reference in its entirety.

An active region can comprise a single active layer. In a single layer-active region the composition of the material forming the single-layer active region can be uniform throughout the single-layer active region or can vary continuously across the single layer-active region. An active region can comprise two or more active layers and can be referred to as a multilayer active region. Each of the two or more layers of a multilayer active region can have a different material composition. In a multilayer active region, the composition can vary discretely across the thickness of the multilayer active region. This can be compared to a single layer active region where the composition can vary continuously across the thickness of the single layer-active region.

A multilayer active region can comprise one or more active layers where the material composition forming the one or more active layers varies continuously across the active layer and one or more active layers where the material composition is uniform across the active layer.

The multiplication region 206 can be a p-type III-V layer configured to amplify the current generated by the active region 208 through avalanche multiplication. Thus, for each free carrier (electron or hole) generated by the active region 208, the multiplication region 206 generates one or more carriers via the avalanche effect. Thus, the multiplication layer 206 can increase the total current generated by the semiconductor 200. Multiplication region 206 can comprise a III-V material, such as GaAs or AlGaAs. In some embodiments, multiplication region 206 can include a dilute nitride material such as GaInNAs, GaInNAsSb or GaNAsSb. Examples of semiconductor materials and structures for multiplication regions are described in PCT International Publication No. WO 2019/241450, which is incorporated by reference in its entirety.

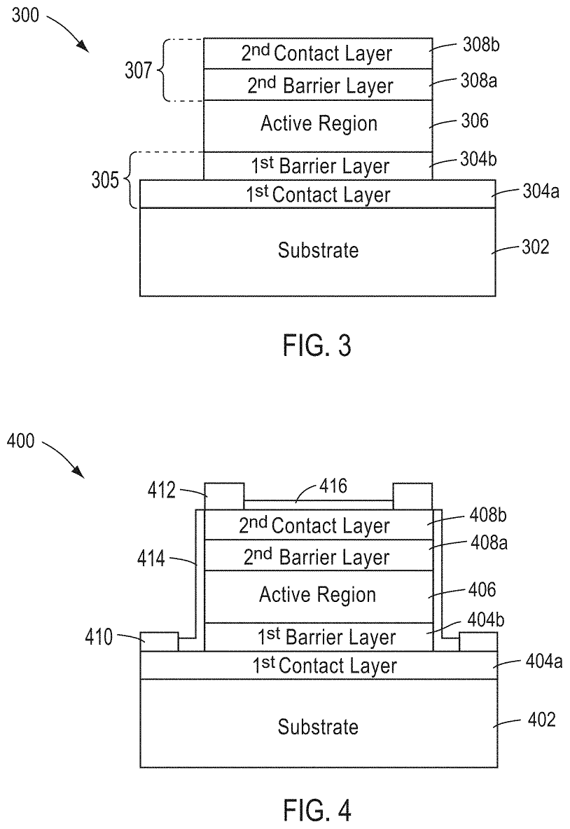

FIG. 3 shows a side view of an example of a semiconductor optoelectronic structure 300 according to the present invention. Structure 300 is similar to structure 100, but each of the doped regions is shown to comprise two layers consisting of a contact layer and a barrier layer. Device 300 includes a substrate 302, a first contact layer 304a, a first barrier layer 304b, an active region 306, a second barrier layer 308a, and a second contact layer 308b.

Substrate 302 can have a lattice constant that matches or nearly matches the lattice constant of GaAs or Ge. The substrate can be GaAs. Substrate 302 may be doped p-type, or n-type, or may be a semi-insulating (SI substrate). The thickness of substrate 302 can be any suitable thickness. Substrate 302 can include one or more layers, for example, substrate 302 can include a Si layer having an overlying SiGeSn buffer layer that is engineered to have a lattice constant that matches or nearly matches the lattice constant of GaAs or Ge. This can mean that the substrate can have a lattice parameter different than that of GaAs or Ge by less than or equal to 3%, less than 1%, or less than 0.5% that of GaAs or Ge.

First contact layer 304a and first barrier layer 304b provide a first doped region 305, having a doping of one type, and second barrier layer 308a and second contact layer 308b provide a second doped region 307, having a doping of the opposite type. If first doped region 305 is doped n-type, second doped region 307 is doped p-type. Conversely, if first doped region 305 is doped p-type, second doped region 307 is doped n-type. Examples of p-type dopants include C and Be. Examples of n-type dopants include Si and Te. Doped regions 305 and 307 can be chosen to have a composition that is lattice-matched or pseudomorphically strained with respect to the substrate. The doped regions can comprise any suitable III-V material, such as GaAs, AlGaAs, GaInAs, (Al)GaInP, (Al)GaInPAs, AlInP, GaInNAs, and GaInNAsSb. The contact and barrier layers can have different compositions and different thicknesses. The bandgap of the doped regions can be selected to be larger than the bandgap of active region 306. The doping level of first contact layer 304a can be chosen to be higher than the doping level of first barrier layer 304b. A higher doping level facilitates electrical connection with a metal contact. Similarly, the doping level of second contact layer 304b can be chosen to be higher than the doping level of second barrier layer 304a. Higher doping levels facilitate electrical connection with a metal contact. Doping levels for the contact layers and for the barrier layers can independently be within a range, for example, from 1×10¹⁵ cm⁻³ to 2×10¹⁹ cm⁻³, from 1×10¹⁶ cm⁻³ to 2×10¹⁸ cm⁻³, 2×10¹⁶ cm⁻³ to 1×10¹⁸ cm⁻³, or from 1×10¹⁷ cm⁻³ to 1×10¹⁹ cm⁻³. Doping levels may be constant within a layer and/or the doping profile may be graded, for example, the doping level can increase from a minimum value to a maximum value as a function of the distance from the interface between the doped layer 308a and the active region 306. Each of barrier and contact layers 304a, 304b, 308a and 308b can independently have a thickness, for example, within a range from 50 nm to 3 μm, from 100 nm to 2.5 μm, from 200 nm to 2 μm, or from 500 nm to 1.5 μm.

Active region 306 can be lattice-matched or pseudomorphically strained with respect to the substrate and/or to the barrier layers. The maximum bandgap of active region 306 can be lower than that of each of barrier and contact layers 304a, 304b, 308a and 308b. For example, the maximum bandgap of active region can be at least 25 meV less than the minimum bandgap of each of the barrier and contact layers, at least 50 meV, at least 100 meV, at least 200 meV less, at least 300 meV less, at least 400 meV less, or at least 500 mV less than the minimum bandgap of each of the barrier and contact layer. The maximum bandgap of active region 306 can independently be from 25 meV to 1,000 meV less than the minimum bandgap of each of the barrier and contact layers, from 50 meV to 800 mV, from 100 meV to 600 meV, or from 200 meV to 500 meV less than the minimum bandgap of each of the barrier and contact layers.

Active region 306 can include a dilute nitride material. A dilute nitride material can include GaInNAs, GaNAsSb, GaInNAsSb, GaInNAsBi, GaNAsSbBi, GaNAsBi, and/or GaInNAsSbBi. In some embodiments, the dilute nitride material can be Ga₁₋ₓInₓN_{y}As_{1-y-z} Sb_{z}, where x, y and z can be 0≤x≤0.4, 0≤y≤0.07 and 0≤z≤0.04, respectively. X, y and z can be 0.01≤x≤0.4, 0.02≤y≤0.07 and 0.001≤z≤0.04, respectively. In other embodiments, a dilute nitride material can have composition as disclosed in U.S. Pat. No. 8,962,993, where x, y and z can be 0≤x≤0.24, 0.02≤y≤0.05 and 0.001≤z≤0.2, respectively. A dilute nitride material can be Ga₁₋ₓInₓN_{y}As_{1-y-z}Sb_{z}, where, for example, 0.12≤x≤0.24, 0.03≤y≤0.07 and 0.005≤z≤0.04; 0.13≤x≤0.2, 0.03≤y≤0.045 and 0.001≤z≤0.02; 0.13≤x≤0.18, 0.03≤y≤0.04 and 0.001≤z≤0.02; or 0.18≤x≤0.24, 0.04≤y≤0.07 and 0.01≤z≤0.04.

Active region 306 can have a bandgap within a range from 0.7 eV to 1.3 eV such that the active region can absorb or emit light at wavelengths up to 1.8 μm. Bismuth (Bi) may be added as a surfactant during growth of the dilute nitride, improving material quality (such as defect density), and the device performance. The thickness of active region 306 can be, for example, within a range from 0.2 μm to 10 μm, from 0.5 μm to 8 μm, from 1.0 μm to 6 μm, from 1.0 μm to 5 μm, from 1 μm to 4 μm, from 1 μm to 3 μm, or from 1 μm to 2 μm. The carrier concentration of the active region can be, for example, less than 1×10¹⁶ cm⁻³ (measured at room temperature (25° C.), less than 5×10¹⁵ cm⁻³, or less than 1×10¹⁵ cm⁻³. Active region 306 can be compressively strained with respect to the substrate 302. Strain can also improve device performance. For a photodetector, the parameters most relevant to device performance include the dark current, operating speed, noise and responsivity.

Active region 306 is shown as a single layer, but it will be understood that active region 306 can include more than one active layer with each active layer having a different bandgap. For example, each active layer can independently have a bandgap within a range from 0.7 eV and 1.4 eV. An active region can comprise, for example, from 2 to 10 active layers, from 2 to 9 active layers, from 2 to 8 active layers, from 2 to 7 active layers, from 2 to 6 active layers, from 2 to 5 active layers, from 2 to 4 active layers or from 2 to 3 active layers. Each of the active layers can have a bandgap that is different from each of the other active layers. At least some of the active layers can have a bandgap that is different than that of other active layers. In an active layer, the elemental composition of the material forming the active layer such as a dilute nitride material, such as Ga₁₋ₓInₓN_{y}As_{1-y-z} Sb_{z}, can have a substantially uniform composition throughout the in-plane dimension and in the growth dimension. For example, a substantially uniform composition can be substantially uniform elemental composition. For example, in a substantially uniform elemental composition the content of each element can differ by less than 1%, by less than 2%, or by less than 5%.

Each active layer forming an active region can independently have a uniform bandgap. For example, in an active layer having a uniform bandgap the bandgap throughout the in-plane dimension and in the growth dimension can differ, for example, by less than 0.010 eV, by less than 0.015 eV, or by less than 0.02 eV. An active layer can have a bandgap that is the same or that is different than other active layers forming the active region.

An active region can comprise one or more active layers having a doping profile. A doping profile can vary across the growth direction of the active layer. An active layer can comprise, for example, a linear doping profile, a non-linear doping profile, an exponential doping profile, or a combination of any of the foregoing. An active layer can comprise a constant doping profile. An active layer can comprise a portion having intrinsic doping. An active layer can comprise portions in the growth dimension that are intrinsically doped, intentionally doped, or a combination thereof. An active layer can comprise a portion that is intrinsically doped, a portion that has a constant doping profile, a portion that has a linear doping profile, a portion that has a non-linear doping profile, or a combination of any of the foregoing. An active layer and/or a portion of an active layer can be p-doped or n-doped.

An active region 306 can include regions with different doping profiles. Examples of doping profiles for dilute nitride materials are described in U.S. Application Publication No. 2016/0118526, which is incorporated by reference in its entirety.

An active region can have a non-uniform composition in the thickness dimension (i.e. in the growth direction, orthogonal to surface of a layer). For example, the elemental composition of the active region can vary linearly or non-linearly across that thickness of the active region. The elemental composition of the active region can vary linearly or non-linearly across a portion of the thickness of the active region. Non-limiting examples of non-linear monotonically-varying profiles include quadratic profiles, polynomial profiles, square root profiles and exponential profiles, as well as discontinuous profiles with compositional steps. For example, in a non-uniform composition the content of at least one element can vary by greater than 5%, greater than 10%, greater than 15% or greater than 20%, across the active region.

A non-uniform active region can have a bandgap that varies across the thickness dimension. The bandgap can vary linearly or non-linearly such as quadratically or exponentially. The bandgap can vary, for example, by at least 40 meV across the thickness of the non-uniform active region, by at least 60 meV, by at least 100 meV, by at least 200 meV, by at least 400 meV, by at least 600 meV, or by at least 800 meV. The bandgap can vary, for example, by from 40 meV to 1,000 meV, from 40 meV to 700 meV, or by from 40 meV to 400 meV.

FIG. 4 shows a side view of an example of a photodetector 400 according to the present invention. Device 400 is similar to device 300. Compared to device 300, additional device layers include a first metal contact 410, a second metal contact 412, a passivation layer 414, and an antireflection coating 416. The semiconductor layers 402, 404a, 404b, 406, 408a and 408b correspond to layers 302, 304a, 304b, 306, 308a and 308b, respectively, of device 300. Multiple lithography and materials deposition steps may be used to form the metal contacts, passivation layer, and antireflection coating. The device has a mesa structure, produced by etching. This exposes the underlying layers. A passivation layer 414 is provided that covers the side-walls of the device and the exposed surfaces of the layers so as to reduce surface defects and dangling bonds that may otherwise affect device performance. The passivation layer can be formed using a dielectric material such as silicon nitride, silicon oxide, or titanium oxide. Anti-reflection layer 416 overlies a first portion of second contact layer 408a. The antireflection layer can be formed using a dielectric material such as silicon nitride, silicon oxide, and titanium oxide. A first metal contact 410 overlies a portion of the first contact layer 404a. A second metal contact 412 overlies a second portion of second contact layer 408b. Metallization schemes for contacting to n-doped and p-doped materials are known. Photodetector 400 can be illuminated from the top surface of the device, i.e. through the interface between anti-reflection coating 416 and air. A photodetector may be illuminated via the bottom surface, i.e. the interface between the lower surface of the substrate 402 and air. The bottom surface of the substrate may be coated with an anti-reflection coating. Incident optical radiation on a detector will generate an electronic signal at the detector.

Examples of dilute nitride semiconductor photodetectors are described in PCT International Publication No. WO 2019/067553A1, which is incorporated by reference in its entirety.

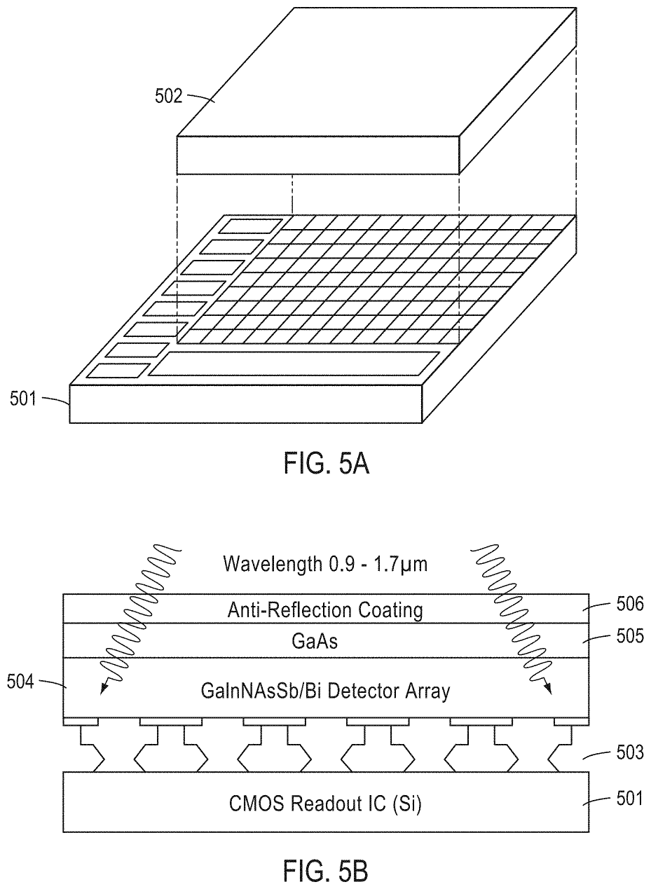

For an array of detectors, the collected signals may be amplified by a readout integrated circuit (ROIC) comprising a transistor or a trans-impedance amplifier to form a Focal Plane Array (FPA). Examples of photodetector arrays are shown in FIGS. 5A and 5B. FIG. 5A shows a perspective view of a photodetector array including CMOS readout IC 501, and photodetector array 502. FIG. 5B shows a cross-sectional view of CMOS readout IC 501 interconnected to photodetector array 502 through interconnects 503. Photodetector array 502 includes an array of photodetectors provided by the present invention 504, a conversion layer 505, and an antireflection coating 506.

Reduced dark currents may be achieved in devices where the dilute nitride active layer or region has at least two bandgaps associated with different elemental compositions of the dilute nitride material within the active layer or region. The active region can be characterized by a maximum bandgap difference, which refers to the difference between the highest bandgap and the lowest bandgap material within the active region. In a dilute nitride active region, the difference between the highest bandgap of the dilute nitride material and the lowest bandgap of the dilute nitride material is the maximum bandgap difference. A bandgap difference of an active region such as a dilute nitride active region, can be, for example, greater than 40 meV, greater than 50 meV, greater than 100 meV, greater than 250 meV, greater than 500 meV, or greater than 1,000 meV. A bandgap difference of an active region such as a dilute nitride active region, can be, for example, greater less than 50 meV, less than 100 meV, less than 250 meV, less than 500 meV, or less than 1,000 meV. A bandgap difference of an active region such as a dilute nitride active region can be, for example, from 40 meV to 1,000 meV, from 50 meV to 800 meV, from 100 meV to 700 meV, or from 200 meV to 600 meV.

Dark current for a photodetector is the current that can flow in the device when it is under bias but is not exposed to a light source, and thus acts as a noise source. Dark current is one of the contributors to the reduction of the signal-to-noise ratio of a photodetector and it is desirable to reduce the dark current to enhance photodetector performance. The dark current is related to the intrinsic (or background) carrier concentration within a semiconductor material. For semiconductor materials, the intrinsic carrier concentration, nᵢ, can depend exponentially on the material bandgap E_{g} as:

nᵢ=\sqrt{N_{c}Nᵥ}e^{-E}^{_{g}}^{/2kT}

where N_{c} is the effective density of states in the conduction band, Nᵥ is the effective density of states in the valence band, k is Boltzmann's constant and T is the temperature. High bandgap semiconductor materials typically have lower dark current than low bandgap materials. For dilute nitride materials, the inclusion of N into the semiconductor introduces defects into the material. The addition of Sb to a dilute nitride alloy, as well as thermal annealing have been shown to improve crystallinity and lower the background carrier concentration. The background carrier concentration of an intrinsic or unintentionally doped dilute nitride active region, can be, for example, less than 1×10¹⁶ cm⁻³ (measured at room temperature (25° C.), less than 5×10¹⁵ cm⁻³, or less than 1×10¹⁵ cm⁻³. The background carrier concentration may be higher at lower bandgaps, than at higher bandgaps, associated with higher high N compositions usually required for such lower bandgaps. The background carrier concentration of the intrinsic or unintentionally doped active region, which is equivalent to the dopant concentration, can be, for example, less than 1×10¹⁶ cm⁻³ (measured at room temperature (25° C.), less than 5×10¹⁵ cm⁻³, or less than 1×10¹⁵ cm⁻³. Consequently, reducing the thickness of lower bandgap materials can be desirable. For devices with the same active region thickness, by using a graded or stepped bandgap active region, a semiconductor optoelectronic device having an active region with a minimum bandgap can have a lower dark current and lower dark noise than that for an equivalent device that has an active region with a constant bandgap that is equivalent to the minimum bandgap. For example, the dark current can be reduced by more than a factor of 10 or by more than a factor of 100. By using a graded or stepped bandgap active region, a semiconductor optoelectronic device with an active region having a minimum bandgap can have a signal-to-noise ratio that is higher than that for the same device except that the active region has a constant bandgap that is equivalent to the minimum bandgap.

A dilute nitride active region can include, for example, at least two portions of a single-layer active region or at least to layers of a multiple layer active region, having differing compositions, each having a different bandgap. A higher bandgap region may be used to absorb light up to a certain wavelength, while a lower bandgap region may be used to absorb longer wavelengths. The responsivity of the higher wavelength range absorbed in the second region may be maintained using additional structures. Consequently, it can be possible to reduce the dark current (when compared to a single region of low bandgap dilute nitride) by reducing the thickness of the lower bandgap material, while maintaining the responsivity of the device.

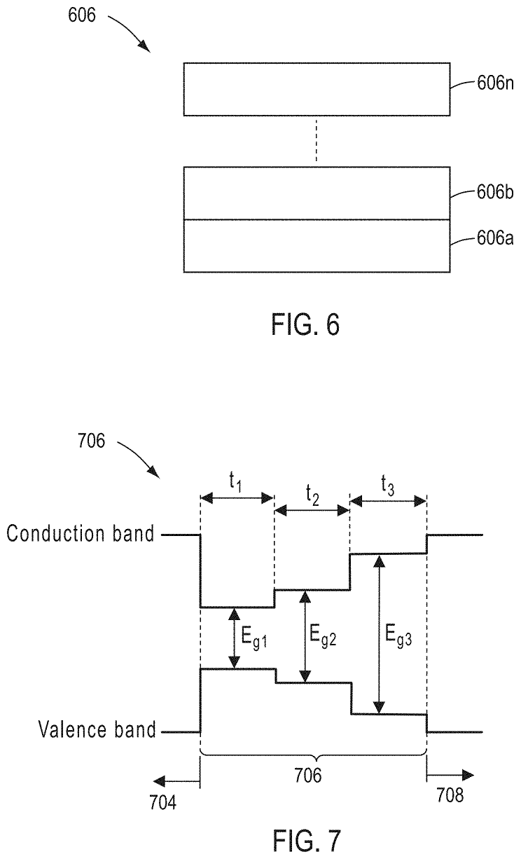

FIG. 6 shows a schematic cross-section of a dilute nitride active region 606 that may be included in a device such as device 100, 200, 300 or 400, according to an embodiment of the invention. Active region 606 includes a first active layer 606a having a first bandgap (E_{g1}) and a first thickness (t₁) and at least a second active layer 606b having a second bandgap (E_{g2}) that is different from the first bandgap and a second thickness t₂. Additional active layers, each having different bandgaps may also be included. FIG. 6 shows the possibility for n active layers stacked together, each with a different bandgap, with the bandgap of the n^{th} layer denoted E_{gn}. The bandgap change within the multiple layer structure can be, for example, either monotonically increasing or monotonically decreasing within the multilayer structure. The bandgaps for the layers may be arranged such that E_{g1}<E_{g2}< . . . <Egₙ₋₁<E_{gn}, for example, or E_{g1}>E_{g2}> . . . >Egₙ₋₁>E_{gn}. The thickness of each of the active layers may, independently, be from 0.05 μm and 7.5 μm, such as from 0.1 μm to 5 μm, from 0.5 μm to 4 μm, or from 1 μm to 3 μm. The bandgap difference between the highest bandgap and the lowest bandgap can be, for example, at least 40 meV, or the bandgap difference can be less than 700 meV. Each of the active layers can comprise a dilute nitride material such as GaInNAsSb.

FIG. 7 shows a band edge alignment for a dilute nitride active region 706 according to an example in FIG. 6, where three different active layers form the active region, sandwiched between first doped region 704 and second doped region 708. First and second doped regions 704/708 may have opposite doping types, as described for device 100, 200, 300 and 400, and with compositions as described for device 100, 200, 300 and 400, with bandgaps larger than any of the bandgaps of the dilute nitride active region 706. In this example, dilute nitride active region 706 includes a first active layer having a bandgap E_{g1}, and thickness t₁, a second active region having a bandgap E_{g2} that is greater than E_{g1} and thickness t₂, and a third active region having a bandgap E_{g3} that is greater than E_{g2} and thickness t₂, forming an active region with a discontinuous or stepped bandgap profile. Each of the active layers in dilute nitride active region 706 can comprise a dilute nitride material.

A photodetector device including active region 706 can be illuminated from the top surface of the device, with light passing through second doped region 708 into the active region 706. The shortest wavelengths of light, corresponding to bandgaps larger than E_{g3} but less than the bandgap of second doped region 708 can be absorbed primarily by the third active layer, but may also be absorbed in the second and first active layers, depending on the layer thicknesses for each active layer. A second set of wavelengths, corresponding to energies between E_{g2} and E_{g3} can be absorbed primarily by the second active layer, but may also be absorbed in the first active layer, depending on the layer thicknesses for each active layer. The longest wavelengths, corresponding to energies between E_{g1} and E_{g2} can be absorbed by the first active layer. The thickness of this active layer may be reduced, when compared to a device with a single active layer having a bandgap E_{g1}. To increase the absorption within at least the first active layer, non-absorbed light may be reflected back into active region 706 using an underlying reflector. Thus, in some embodiments, a distributed Bragg reflector (DBR) or a chirped distributed Bragg reflector (CDBR) may underlie active region 906. Examples of CDBRs are described in U.S. Publication No. 2019/028143A1, which is incorporated by reference in its entirety.

The wavelength range that may be absorbed by active region 706 can in part be determined by the minimum bandgap within the active region and the bandgap of overlying second doped region 708. For a GaAs doped region, the minimum wavelength that may be absorbed and detected is about 870 nm. For an (Al)InGaP second doped region, the bandgap is larger, and so the minimum wavelength that may be absorbed and detected can decrease to about 500 nm or 400 nm, depending on the composition of the active region. Therefore, a single detector can be capable of absorbing light in both visible and SWIR wavelength ranges.

In active region 706, the number of active layers, the respective bandgaps and the respective thicknesses may be chosen to approximate any function for the bandgap change including a linear bandgap change or a non-linear bandgap change. The bandgap difference between the highest and lowest bandgaps can be, for example, from 40 meV to 700 meV.

The bandgap for each active layer of active region 706 may be adjusted by changing the temperatures of the group III sources for each active layer, thereby controlling the growth rates and the semiconductor alloy composition (hence the bandgap). The bandgap for each active layer of active region 706 may also be adjusted by altering the ratio of the group V elements during growth, the ratio between the group III fluxes and the group V fluxes, and/or by changing the substrate temperature.

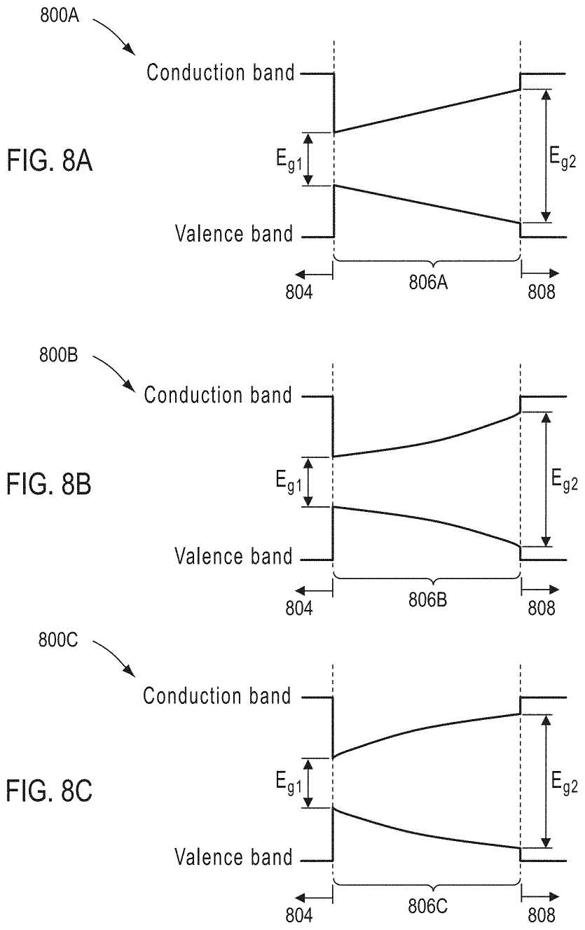

Graded bandgaps may be used instead of stepped bandgap structures, as shown in FIGS. 8A, 8B and 8C, which include graded bandgap active regions 806A, 806B, or 806C sandwiched between first doped region 808 and second doped region 804. A photodetector device including active regions 806A, or 806B or 806C can be illuminated from the top surface of the device, with light passing through second doped region 808 into the active region.

FIG. 8A shows an example of an active region 806A having a linear bandgap variation from a bandgap of E_{g1} at the interface with first doped region 804 to a bandgap of E_{g2} at the interface with second doped region 808. The minimum bandgap difference is about 40 meV, and the largest bandgap difference is about 700 meV.

FIG. 8B shows an example of an active region 806B having a non-linear bandgap variation from a bandgap of E_{g1} at the interface with first doped region 804 to a bandgap of E_{g2} at the interface with second doped region 808. In this example, the bandgap of active region 806B increases from E_{g1} to E_{g2} with the bandgap increasing as a function of the position within the active region. The minimum bandgap difference is about 40 meV and the largest bandgap difference is about 700 meV. The bandgap can be implemented, for example, using a quadratic profile, an exponential profile, or other continuous profile, as a function of distance away from the interface between layer 804 and active region 806B. Other non-linear profiles may also be used.

FIG. 8C shows an example of an active region 806C having a non-linear bandgap variation from a bandgap of E_{g1} at the interface with first doped region 804 to a bandgap of E_{g2} at the interface with second doped region 808. In this example, the bandgap of active region 806B increases in value from E_{g1} to E_{g2} with the bandgap decreasing as a function of the position within the active region. The minimum bandgap difference is about 40 meV and the largest bandgap difference is about 700 meV. The bandgap profile can be implemented, for example, using a logarithmic profile as a function of distance from the interface between layer 804 and active region 806B, though other non-linear profiles may also be used.

The bandgap for active region 806A, 806B and 806C may be adjusted by changing the temperatures of the group III sources during growth of the layer, thereby controlling the growth rates and the semiconductor alloy composition (hence the bandgap). The bandgap for active region 806A, 806B and 806C may also be adjusted by altering the ratio of the group V elements during growth, the ratio between the group III fluxes and the group V fluxes, and/or by changing the substrate temperature. The bandgap for active region 806A, 806B and 806C may also be adjusted by growing the material as a digital alloy superlattice, where the average composition in a portion of the layer (in the direction of growth) is determined by the compositions and thicknesses of each of the superlattice layers in that portion.

Active regions according to the invention may also incorporate both composition steps and composition grades within the composition steps.

Examples of devices having graded or stepped dilute nitride active regions are described in co-pending U.S. application Ser. No. 16/810,427 filed on Mar. 5, 2020, which is incorporated by reference in its entirety.

Dilute nitride absorber materials may also be used as subcells within multijunction solar cells. Multijunction solar cells incorporating dilute nitride subcells are described in U.S. Pat. Nos. 8,575,473; 8,697,381; 8,912,433; and 8,962,993, and in U.S. Application Publication No. 2019/0189826, each of which is incorporated by reference in their entirety. The dilute nitride material can include GaInNAs, GaNAsSb, GaInNAsSb, GaInNAsBi, GaNAsSbBi, GaNAsBi, and/or GaInNAsSbBi. In some embodiments, a dilute nitride materials can have the composition Ga₁₋ₓInₓN_{y}As_{1-y-z}Sb_{z} where x, y and z can be 0≤x≤0.24, 0.02≤y≤0.05 and 0.001≤z≤0.2, respectively, or where, 0.12≤x≤0.24, 0.03≤y≤0.07 and 0.005≤z≤0.04; or 0.13≤x≤0.2, 0.03≤y≤0.045 and 0.001≤z≤0.02; or 0.13≤x≤0.18, 0.03≤y≤0.04 and 0.001≤z≤0.02; or 0.18≤x≤0.24, 0.04≤y≤0.07 and 0.01≤z≤0.024, or 0.08≤x≤0.24, 0.02≤y≤0.05 and 0.001≤z≤0.02.

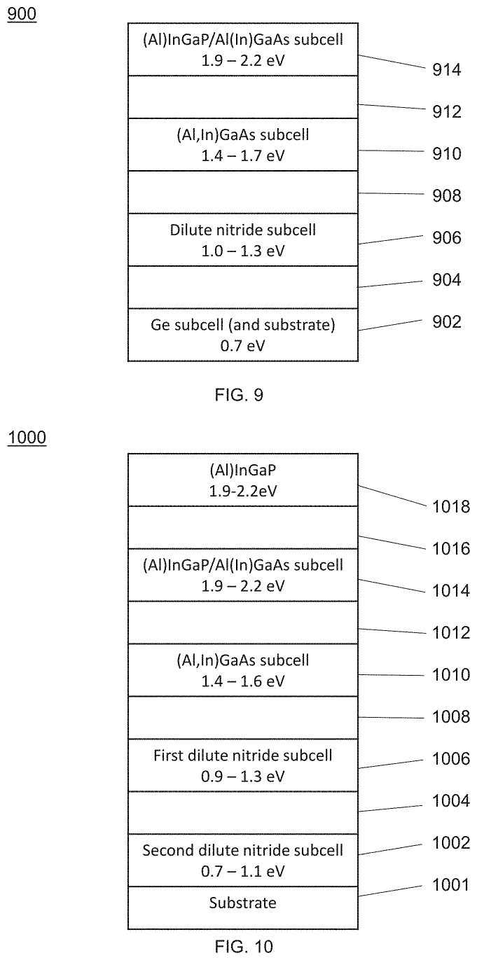

FIG. 9 shows a simplified schematic cross-section of an example of a four-junction multijunction solar cell 900 with a dilute nitride subcell according to the present invention. Device 900 includes a Ge subcell 902, with a bandgap of about 0.7 eV. Ge may also serve as a substrate upon which device 900 is formed, or Ge may be grown on a substrate such as GaAs or an engineered substrate with a lattice constant closely matching that of Ge or GaAs. A tunnel junction 904 overlies Ge subcell 902 and a dilute nitride subcell 906 overlies tunnel junction 904. A second tunnel junction 908 overlies dilute nitride subcell 906 and an (Al,In)GaAs subcell 910 overlies tunnel junction 908. A further tunnel junction 912 overlies subcell 910 and a further subcell 914 overlies tunnel junction 912. All subcells and tunnel junctions are substantially lattice matched to each other and to the substrate. The bandgap of the dilute nitride subcell is in a range from about 1.0 to 1.3 eV. The bandgaps of the subcells (also known as junctions) are arranged in monotonically increasing bandgap order from the substrate to the uppermost subcell, as is known in the art.

FIG. 10 shows a simplified schematic cross-section of an example of a five-junction multijunction solar cell 1000 with two dilute nitride subcells according to the present invention. Device 1000 includes a substrate 1001, such as GaAs or Ge or an engineered substrate with a lattice constant approximately equal to that of Ge or GaAs. A dilute nitride subcell 1002 overlies substrate 1001. Dilute nitride subcell 1002 has a bandgap that is smaller than the bandgap of any of the overlying subcells (or junctions). A tunnel junction 1004 overlies dilute subcell 1002 and an additional dilute nitride subcell 1006 overlies tunnel junction 1004. A second tunnel junction 1008 overlies dilute nitride subcell 1006 and an (Al,In)GaAs subcell 1010 overlies tunnel junction 908. A third tunnel junction 1012 overlies subcell 1010 and a further subcell 1014 overlies tunnel junction 1012. A fourth tunnel junction 1016 overlies subcell 1014 and a further subcell 1018 overlies tunnel junction 1016. All subcells and tunnel junctions are substantially lattice matched to each other and to the substrate. The bandgap of dilute nitride subcell 1002 is in a range between from about 0.7 to 1.1 eV. The bandgap of dilute nitride subcell 1006 is larger than the bandgap for dilute nitride subcell 1002 and is in a range between from about 0.9 to 1.3 eV. As with device 900. The bandgaps of the subcells (also known as junctions) in device 1000 are arranged in monotonically increasing bandgap order from the substrate to the uppermost subcell, as is known in the art.

An individual subcell within multijunction solar cells 900 and 1000 may also include other layers, such as window layers, emitter layers, back surface field layers, and front-surface-field layers, which are not shown. For example, a dilute nitride base layer in a dilute nitride subcell may be adjacent to and overlie an (In)GaAs back surface field layer that has a larger bandgap than the dilute nitride base, and an (In)GaAs emitter layer that has a larger bandgap than the dilute nitride base overlies and is adjacent to the dilute nitride base layer, as in known in the art. The adjacent layers may or may not be doped. The emitter composition and thickness and the back surface field layer composition and thickness may or may not be identical.

Devices 900 and 1000 may also include other layers such as buffer layers and antireflection coating layers, also not shown.

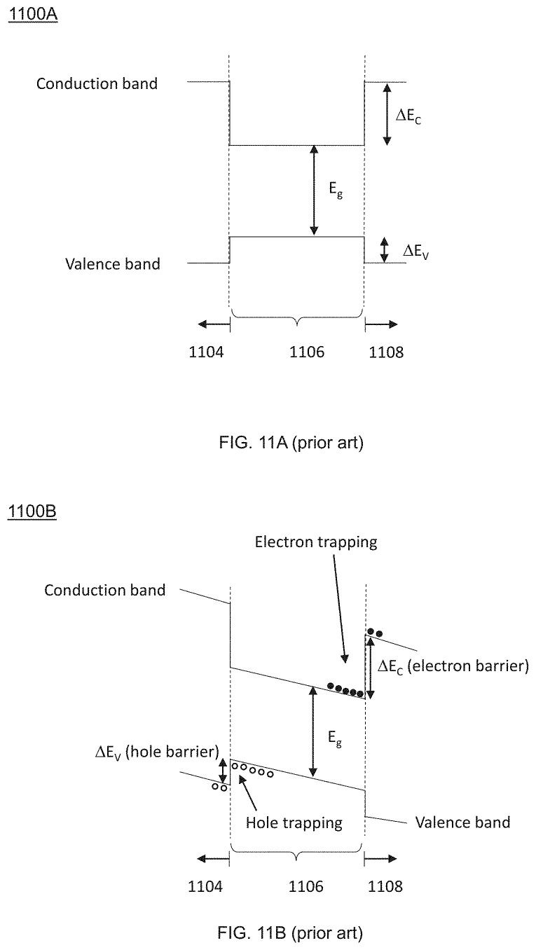

The heterojunctions formed between the dilute nitride material and adjacent layers in dilute nitride optical absorption structures and devices 100, 200, 300, 400, 600, 700, 800, 900 and 1000 can cause carrier trapping of electrons at conduction band discontinuities and trapping of holes at valence band discontinuities. This can reduce the efficiency of a device. Charge carriers can interact with nitrogen-related defects within the material, causing electrical losses, and the flow of carriers across the heterointerfaces that can be collected may be reduced by the heterobarriers. Trapping of carriers may also reduce the response speed of a photodetector. Carrier trapping is shown schematically in FIGS. 11A and 11B. The dilute nitride layer 1106 has a bandgap E_{g}, and layers 1104 and 1108 have bandgaps larger than E_{g}. In a photodetector, layers 1104 and 1108 may both be GaAs, with a conduction band offset ΔE_{C} and a valence band offset ΔEᵥ at both interfaces. A dilute-nitride base region in a solar cell may have different band offset values with layers 1104 and 1108. For example, dilute nitride base layer 1106 may be adjacent to an InGaAs emitter layer 1104 and a GaAs back surface field layer 1108. As the bandgap of the dilute nitride layer 1106 decreases, the band offsets ΔEc and ΔEv typically both increase, with the majority of the band offset incorporated in the conduction band (that is, ΔEc>ΔEv) due to an increase in nitrogen content and associated band bowing. Thus, electron trapping in particular can be a problem for dilute nitride material. In some applications, applying a voltage bias may be used (such as in a photodetector) to reduce the barrier height. However, some applications have no applied bias (such as in a solar cell) or require a small voltage bias only, thus it is necessary to reduce the barrier height at the heterointerface.

A reduction in the barrier height may be achieved using a continuously graded or stepped bandgap interface layer having an associated change in composition. This may also be accomplished using a superlattice design for the graded or stepped interface layers. A graded or stepped interface layer can be implemented adjacent at least one heterointerface. A graded or stepped interface may be used at a heterobarrier to reduce electron trapping. A graded or stepped interface layer can be used at a heterobarrier to reduce hole trapping. A graded or stepped interface layer can be used at both heterobarriers to reduce both electron and hole trapping.

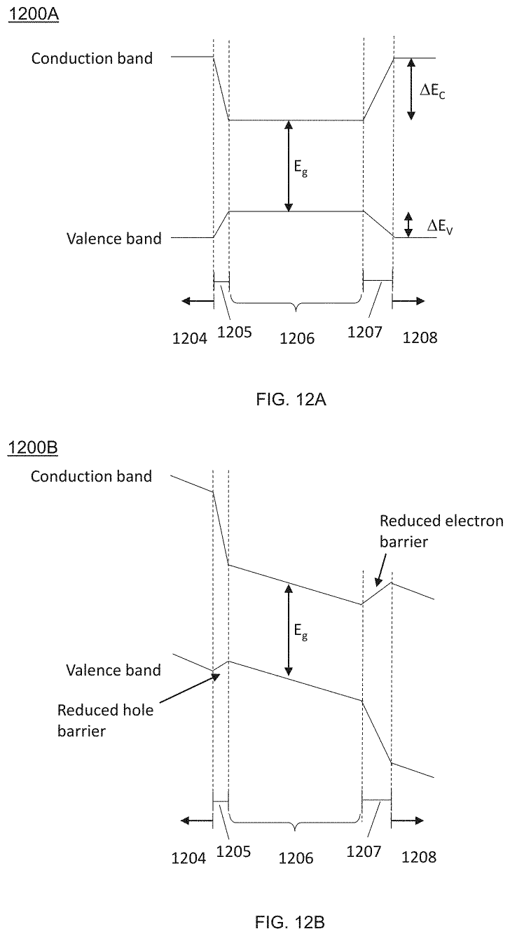

FIGS. 12A and 12 B show band edge alignment diagrams for examples of dilute nitride based heterostructures with graded interfaces according to the present invention. The dilute nitride absorber layer 1206 has a composition Ga₁₋ₓInₓN_{y}As_{1-y-z}Sb_{z} and a bandgap E_{g} with graded interface layers 1205 and 1207 between absorber layer 1206 and adjacent cladding layers 1204 and 1208, each with an associated bandgap, which may be the same or may be different. Cladding layers 1204 and 1208 can be GaAs. As shown, the bandgap associated with the composition of each graded interface layer 1205 and 1207 is, independently, linear, and each graded interface layer transitions the bandgap from that of absorber layer 1206 to the composition of the adjacent cladding layer, with the bandgap increasing towards each cladding layer. The graded interface layers may also be implemented using, for example, a quadratic profile, an exponential profile, or other continuous profile. The thickness of each graded interface layer can independently be less than about 100 nm or less than about 20 nm or less than about 10 nm. A device with a graded interface layer may have one such graded interface (layer 1205 or 1207) or may have both graded interface layers 1205 and 1207. Graded interface layer 1207 can be used to provide a reduced electron barrier, reducing electron trapping. Graded interface layer 1205 can be used to provide a reduced hole barrier, reducing hole trapping.

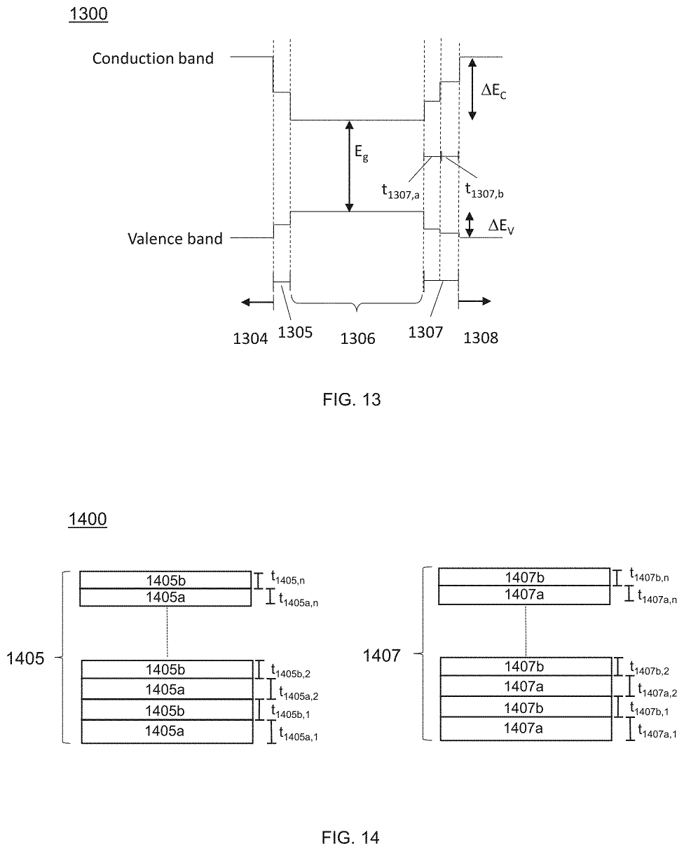

FIG. 13 shows a band edge alignment diagram for an example of a dilute nitride based heterostructure with graded interfaces according to the present invention. The structure shown in FIG. 13 is similar to the structure in FIG. 12, except the graded interface layers 1305 and 1307 are implemented using a discontinuous or stepped composition change, with an associated stepped bandgap change. By way of example, graded interface layer 1305 has one composition with one bandgap intermediate between that of the dilute nitride absorber layer 1306 and the cladding layer 1304, while graded interface layer 1307 is shown to have two steps for composition and bandgap intermediate between that of the dilute nitride absorber layer 1306 and the cladding layer 1308, each step having thicknesses t_{1307,a} and t_{1307,b}, and each bandgap successively increasing away from the absorber layer 1306 to the cladding layer 1308. Other numbers of steps may also be used. A device with a graded interface layer may have one such graded interface (layer 1305 or 1307) or may have both graded interface layers 1305 and 1307. Graded interface layer 1307 can be used to provide a reduced electron barrier, reducing electron trapping. Graded interface layer 1305 can be used to provide a reduced hole barrier, reducing hole trapping. The compositions and the bandgaps for the graded interface layers may be chosen with respect to the composition and bandgap for the dilute nitride absorber layer as will be described.

With respect to the barrier for electrons, where a reduction in the conduction and offset is desired, the dilute nitride absorber layer 1206 (or 1306) may have a composition Ga₁₋ₓInₓN_{y}As_{1-y-z} Sb_{z}, where 0≤x≤0.4, 0≤y≤0.07 and 0≤z≤0.04, or where 0≤x≤0.24, 0.02≤y≤0.05 and 0.001≤z≤0.3; a bandgap E_{g}; and a conduction band offset ΔE_{c} between the dilute nitride absorber 1206 (or 1306) and the cladding layer (1208 or 1308). The graded interface layer 1207 (or 1307) has a composition Ga₁₋ₓ₁Inₓ₁N_{y1}As_{1-y1-z1}Sb_{z1}, where 0≤x1≤0.4, 0≤y1≤0.07 and 0≤z1≤0.04, or 0≤x1≤0.24, 0.02≤y1≤0.05 and 0.001≤z1≤0.3; a bandgap E_{g1}; and a conduction band offset ΔE_{c1} between the graded interface layer 1207 (or 1307) and the adjacent cladding layer (1208 or 1308), where ΔE_{c1}<ΔE_{c}. At least one of the following design conditions must be met in order to reduce the conduction band offset and hence reduce electron trapping.

In some embodiments the nitrogen composition of the graded interface layer can be reduced with respect to that of the composition of the active layer such that y1<y and E_{g1}>E_{g}. Decreasing the nitrogen composition also decreases the level of nitrogen-related defects in the interface layer (and associated device electrical losses and noise) that otherwise may occur when no graded interface layer is used.

In some embodiments, the indium composition of the graded interface layer is reduced with respect to the composition of the active layer, such that x1<x and E_{g1}>E_{g}.

In some embodiments, the In/Sb ratio is adjusted such that: x/z>x1/z1 and E_{g}<E_{g1}. A lower In/Sb ratio in the graded interface layer may be achieved by decreasing the In composition for a fixed Sb composition, or by increasing the Sb composition (which increases the band offset in the valence band) or by decreasing the In composition at a faster rate than the Sb composition.

In some embodiments, a combination of design conditions may be used, such as reducing the nitrogen content and reducing the indium content.

With respect to the barrier for holes, where a reduction in the valence and offset is desired, the dilute nitride absorber layer 1206 (or 1306) may have a composition Ga₁₋ₓInₓN_{y}As_{1-y-z}Sb_{z}, where 0≤x≤0.4, 0≤y≤0.07 and 0≤z≤0.04, or where 0≤x≤0.24, 0.02≤y≤0.05 and 0.001≤z≤0.2; a bandgap E_{g}; and a conduction band offset ΔEᵥ between the dilute nitride absorber 1206 (or 1306) and the cladding layer (1204 or 1304). The graded interface layer 1205 (or 1305) has a composition Ga₁₋ₓ₁Inₓ₁N_{y1}As_{1-y1-z1}Sb_{z1}, where 0≤x2≤0.4, 0≤y2≤0.07 and 0≤z2≤0.04, or 0≤x2≤0.24, 0.02≤y2≤0.05 and 0.001≤z2≤0.2; a bandgap E_{g2}; and a conduction band offset ΔEᵥ₂ between the graded interface layer 1205 (or 1305) and the adjacent cladding layer (1204 or 1304), where ΔEᵥ₁<ΔEᵥ. At least one of the following design conditions must be met in order to reduce the valence band offset and hence reduce hole trapping.

In some embodiments the nitrogen content of the graded interface layer can be reduced with respect to that of the composition of the active layer such that y2<y and E_{g2}>E_{g}. Decreasing the nitrogen content also decreases the level of nitrogen-related defects in the interface layer (and associated device electrical losses and noise) that otherwise may occur when no graded interface layer is used.

In some embodiments, the antimony content of the graded interface layer can be reduced with respect to that of the composition of the active layer, such that z2<z and E_{g2}>E_{g}. Antimony can contribute to the valence band offset and so reducing the content of Sb can be beneficial.

In some embodiments, the In/Sb ratio can be adjusted such that: x/z<x2/z2 and E_{g}≤E_{g1}. A higher In/Sb ratio in the graded interface layer can be achieved by decreasing the Sb composition for a fixed In composition, or by decreasing the Sb composition at a faster rate than the In composition.

In some embodiments, a combination of design conditions may be used, such as reducing the nitrogen content and reducing the antimony content.

The composition (and bandgap) for each graded interface layer 1205 and 1207 (or 1305 and 1307) can be adjusted by changing the temperatures of the group III sources for each graded interface layer, thereby controlling the growth rates and the semiconductor alloy composition (hence the bandgap). For example, a graded interface may be grown by adjusting the relative growth rates of the Ga and In cells linearly during growth, while maintaining a fixed growth rate, or by using multiple group III cells for Ga and/or In, each operating with a different flux rate, such that combinations of different cells may be used to vary the group Ga/In ration and hence the group III composition. The composition (and bandgap) for each graded interface layer 1205 and 1207 (or 1305 and 1307) may also be adjusted by altering the ratio of the group V elements during growth. This may be achieved through the use of multiple cells for a given element (for example, nitrogen) operating at different flow rates such that the combination of cells allows multiple flow rates to be achieved. Composition may also be changed by changing the ratio between the group III fluxes and the group V fluxes, and/or by changing the substrate temperature. The composition (and bandgap) for each graded interface layer 1205 and 1207 (or 1305 and 1307) may also be adjusted by growing the layers as a digital alloy superlattice.

FIG. 14 shows schematic cross sections of graded compositional interface layers formed using a digital alloy superlattice. A digital alloy is an alloy grown with an average composition that includes two or more different semiconductor components having different compositions. The average composition of the digital alloy depends on the thickness and composition of each of the constituent layer types used to form the superlattice. A digital alloy superlattice can include more than two different layer types, wherein each layer type is periodically repeated in an operationally-controllable fashion (periodically, in a form of A/B/A/B . . . , or A/B/C/A/B/C . . . ) through a superlattice. However, only two-layer types are illustrated in FIG. 14 for simplicity and ease of discussion. The superlattice layers are typically thin, each less than about 10-100 Angstrom (1-10 nm), so that the resulting overall material has the properties of that having the average composition and not of the individual layers constituting the alloy. A superlattice may include layers as thin as one monolayer (approximately 0.283 nm for GaAs). The thickness of the superlattice layers can vary in the thickness direction of the superlattice in order to vary the average composition across the superlattice, providing a compositional grade with an associated bandgap profile. In the examples shown, graded interface layer 1405 contains two semiconductor layers 1405a and 1405b, with thicknesses t₁₄₀₅ₐ and t_{1405b}. More particularly, the thickness of adjacent superlattice pairs may vary, such that a first superlattice pair has thicknesses t_{1405a,1} and t_{1405b,1}, a second superlattice pair has a thicknesses t_{1405a,2} and t_{1405b,2} and so on. The thickness variations across the superlattice provide differing average compositions as a function of the position within the thickness. Similarly, graded interface layer 1407 contains two semiconductor layers 1407a and 1407b, with thicknesses t_{1407a, 1} and t_{1407b,1}, thicknesses t_{1407a,2} and t_{1405b, 2} and so on. Since the superlattice layers may be thin, many superlattice layers may be required to produce a graded interface layer. Each graded interface layer, independently, may be undoped or may be deliberately doped across at least a portion of the thickness of the interface layer.

A change in the average composition may be used to change the band offset in the conduction band and/or the valence band. The average composition change can be accompanied by a bandgap change, or the bandgap may remain approximately constant, with only a chosen band offset decreasing according to the compositional grade.

At least one graded interface layer may be used in conjunction with active layer 106 in device 100, active layer 206 in device 200, active layer 306 in device 300, active layer 406 in device 400, dilute nitride subcell 906 in device 900, dilute nitride subcell 1002 in device 1000 and dilute nitride subcell 1006 in device 1000, the active layers or subcells having either a fixed bandgap or a graded or stepped bandgap as shown in FIGS. 7 and 8.

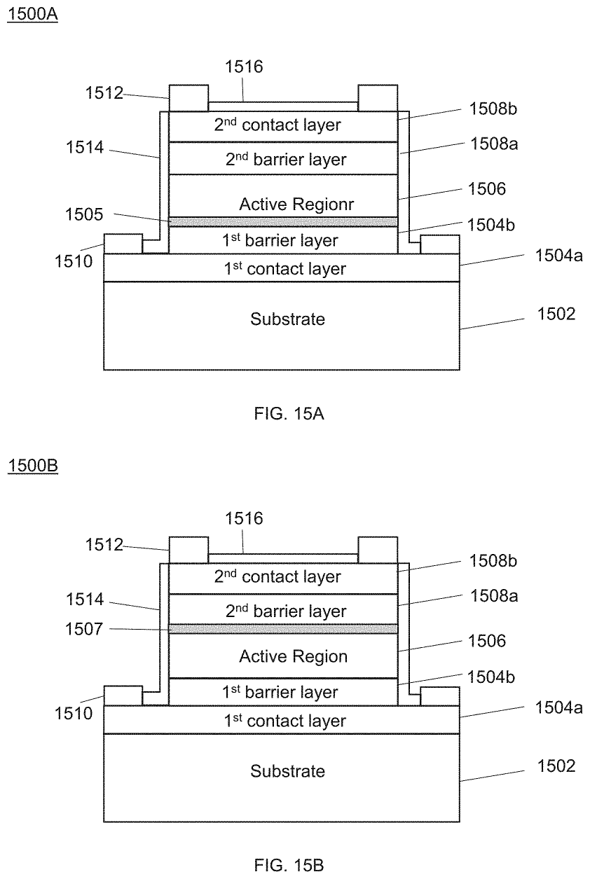

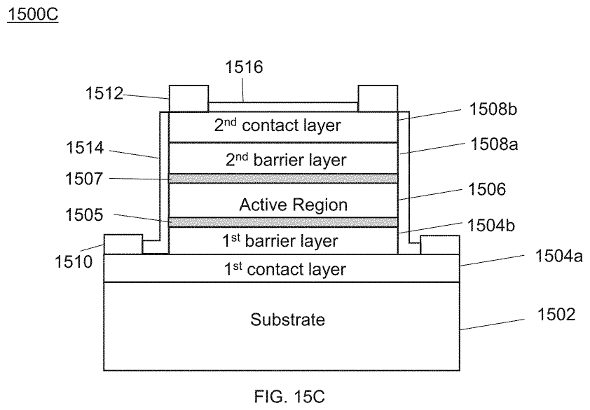

FIG. 15A shows a side view of an example of a photodetector 1500A with a graded interface layer according to the present invention. Device 1500A is similar to device 400, except it shows a graded interface layer 1505 between active layer 1506 and first barrier layer 1504b.

FIG. 15B shows a side view of an example of a photodetector 1500B with a graded interface layer according to the present invention. Device 1500B is similar to device 400, except it shows a graded interface layer 1507 between active layer 1506 and second barrier layer 1508a.

FIG. 15C shows a side view of an example of a photodetector 1500C with a graded interface layer according to the present invention. Device 1500C is similar to device 400, except it shows a graded interface layer 1505 between active layer 1506 and first barrier layer 1504b and a graded interface layer 1507 between active layer 1506 and second barrier layer 1508a.

Interface layers 1505 and 1507 may or may not be intentionally doped.

Semiconductor optoelectronic devices of the present disclosure, such as photodetectors comprising III-V semiconductor layers can be grown on either a GaAs or a Ge substrate. The lattice constants of GaAs and Ge are 5.65 Å and 5.66 Å, respectively, and growth of III-V materials with similar compositions without defects can be grown on either substrate. The close matching of the lattice constants of Ge and GaAs allows, for example, high-quality GaAs to be epitaxially grown on a Ge surface.

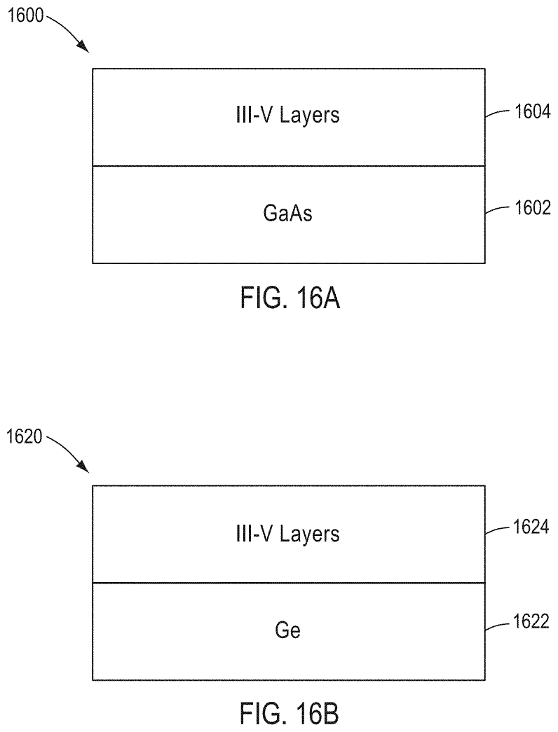

FIGS. 16A and 16B depict semiconductor devices 1600 and 1620, respectively. Semiconductor device 1600 comprises III-V compound semiconductor layers 1304 epitaxially formed over a GaAs substrate 1602, and semiconductor device 1620 comprises semiconductor layers 1624 formed over a Ge substrate 1622. Semiconductor layers 1604 and 1624 are grown lattice-matched or pseudomorphically strained with respect to the substrate, ensuring the formation of high quality III-V layers.

The III-V material can also be grown on a substrate having a lattice constant closely matching that of GaAs or Ge, such as a buffered substrate. Examples of buffered silicon substrates that can provide a lattice constant approximately equal to that of GaAs or Ge include SiGe-buffered Si, SiGeSn-buffered Si, and rare-earth (RE) buffered Si, such as a rare-earth oxide (REO)-buffered Si. As will be understood by one of ordinary skill in the art, a layer such as SiGe, SiGeSn, or a RE-containing layer can form a buffer layer (or lattice engineered layer) grown on a substrate such as Si having a low number of defects and/or dislocations in the lattice engineered layer. The buffer layer can provide a lattice constant at the top of the buffer layer approximately equal to that of a GaAs or Ge substrate, facilitating the ability to form high quality III-V layers on top of the buffer layer, with a low number of defects and/or dislocations in the III-V semiconductor layers and/or dilute nitride layers. A low number of defects can include comparable or fewer defects than would occur in an In_{0.53}Ga_{0.47}As layer grown on an InP substrate.

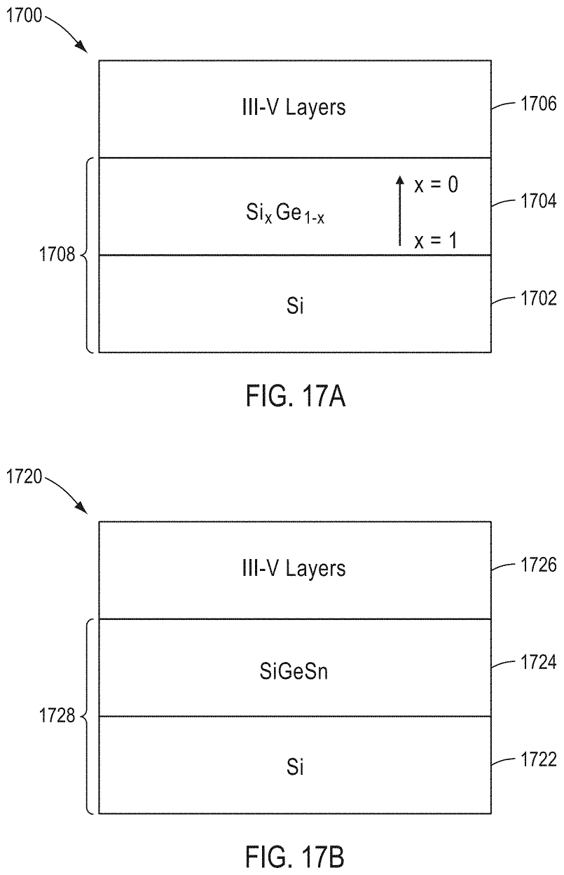

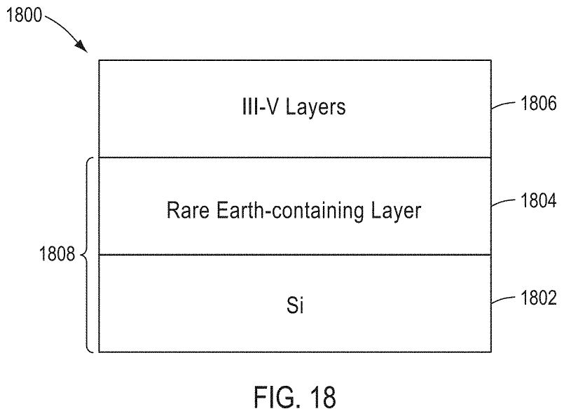

FIGS. 17A, 17B and 18 show examples of III-V materials, such as photovoltaic cells, photodetectors and power converters formed over buffered substrates with lattice parameters matching or nearly matching the lattice constant of GaAs or Ge.

FIGS. 17A and 17B depict semiconductor devices 1700 and 1720, respectively, comprising a lattice-engineered buffer layer over a silicon substrate. Device 1700 comprises a silicon substrate 1702, a graded SiₓGe₁₋ₓ (0≤x≤1) buffer layer 1404 overlying the Si substrate and III-V compound semiconductor layers 1706 overlying the SiGe buffer layer 1704. The Si fraction x of the graded SiₓGe₁₋ₓ layer 1404 varies from 0 to 1 through the layer thickness. At the interface with the Si substrate 1702, x=1 and the graded SiₓGe₁₋ₓ layer 1704 substantially only contains Si. At the interface with the III-V layers 1706, x=0 and the graded SiₓGe₁₋ₓ layer 1704 substantially only contains Ge. Thus, the graded SiₓGe₁₋ₓ layer 1704 provides a transition in lattice parameter from that of the Si substrate (5.43 Å) to that of Ge (5.66 Å), which nearly matches to that of GaAs (5.65 Å). Thus, the graded SiₓGe₁₋ₓ layer 1704 allows for growth of GaAs layers on Si substrates. Together, the graded SiₓGe₁₋ₓ layer 1704 and the silicon substrate 1702 comprise a substrate 1408 having a top surface with a lattice parameter nearly matching that of GaAs or Ge.

As shown in FIG. 17B, device 1720 comprises a silicon substrate 1722, a SiGeSn buffer 1724 overlying the Si substrate and III-V compound semiconductor layers 1726 overlying the buffer 1724. The SiGeSn buffer layer 1724 can be formed according to the method described in U.S. Pat. No. 8,029,905 and can provide a lattice constant approximately equal to that of GaAs or Ge at the interface with the overlying III-V layers 1726, thereby allowing for the growth of GaAs layers on Si substrates. Together, the SiGeSn layer 1724 and the silicon substrate 1722 comprise a substrate 1728 having a top surface with a lattice parameter nearly matching that of GaAs and Ge.

FIG. 18 depicts a semiconductor device 1800 comprising a lattice-engineered buffer layer over a silicon substrate. Device 1900 comprises a silicon substrate 1802, a rare-earth (RE)-containing buffer 1804 epitaxially formed overlying the Si substrate and III-V compound semiconductor layers 1506 overlying the buffer 1804. The RE-containing layer 1804 is a lattice-engineered layer. Rare earth elements are a specific class of elements on the periodic table (Sc, Y, La, Ce, Pr, Nd, Pm, Sm, Eu, Gd, Tb, Dy, Ho, Er, Tm, Yb, Lu). The RE containing layer can comprise one or more of the rare earth elements. Generically, the RE-containing layer can be a rare earth oxide (REO), a rare earth silicide (RESi), or a pnictide (RE-V, where V represents a group V element from the periodic chart, namely N, P, As, Sb, or Bi) or any combination of a REO, a RESi, and/or a pnictide. The composition of the RE-containing layer can be selected to result in a lattice parameter matching or nearly matching GaAs at its interface with an overlying III-V layer 1806. For example, the layer at the interface can be ErAsₓN₁₋ₓ, where x is approximately 0.9, which is lattice-matched or nearly matched to GaAs. The RE-containing layer can have constant composition or a graded composition throughout the layer thickness. When graded, the RE-containing layer can be engineered so that the portion nearest the Si is chemically and mechanically compatible with silicon. For example, gadolinium oxide can be employed at or near the interface between the silicon and RE-containing layer due to its lattice match with silicon. Thus, the RE-containing layer 1804 can provide a template for epitaxial growth of III-V layers 1806. Together, the RE-containing layer 1804 and the silicon substrate 1802 comprise a substrate 1808 having a top surface with a lattice parameter matching or nearly matching that of GaAs or Ge.

The substrates shown in FIGS. 16A to 18 can be used in any of the semiconductor devices shown in FIGS. 1 to 4, 9 to 10 and 15A, 15B and 15C.

Aspects of the Invention

The invention is further defined by the following aspects.

Aspect 1. A compound semiconductor optoelectronic structure, comprising: a substrate having a substrate surface; a first doped region overlying the substrate surface, wherein the first doped region is characterized by a first doped region bandgap; an active region overlying the first doped region, wherein the active region comprises a dilute nitride material, wherein the dilute nitride material is characterized by a dilute nitride material bandgap; a second doped region overlying the active region, wherein the first doped region is characterized by a second doped region bandgap; and a first interface region adjacent to the active region and to the first doped region; or a second interface region adjacent the active region and the second doped region; or a first interface region adjacent to the active region and to the first doped region and a second interface region adjacent the active region and the second doped region; wherein the first interface region is characterized by a first interface region bandgap, and the first interface region bandgap is intermediate between the dilute nitride material bandgap and the first doped region bandgap; and wherein the second interface region is characterized by a second interface region bandgap, and the second interface region bandgap is intermediate between the dilute nitride material bandgap and the second doped region bandgap.

Aspect 2. The structure of aspect 1, wherein the structure comprises a first interface region adjacent to the active region and to the first doped region.

Aspect 3. The structure of aspect 2, wherein the first interface region comprises a dilute nitride material.

Aspect 4. The structure of any one of aspects 2 to 3, wherein the first interface region has a thickness less than 100 nm.

Aspect 5. The structure of aspect 1, wherein the structure comprises a second interface region adjacent the active region and the second doped region.

Aspect 6. The structure of aspect 5, wherein the second interface region comprises a dilute nitride material.

Aspect 7. The structure of any one of aspects 5 and 6, wherein the second interface region has a thickness less than 100 nm.

Aspect 8. The structure of aspect 1, wherein the structure comprises a first interface region adjacent to the active region and to the first doped region and a second interface region adjacent the active region and the second doped region

Aspect 9. The structure of aspect 8, wherein each of the first interface region and the second interface region comprises a dilute nitride material.

Aspect 10. The structure of any one of aspects 8 and 9, wherein each of the first interface region and the second interface region has a thickness less than 100 nm.

Aspect 11. The structure of any one of aspects 1 to 10, wherein, the first interface region comprises one or more interface layers; or the second interface region comprises one or more interface layers; or each if the first interface region and the second interface region independently comprises one or more interface layers.

Aspect 12. The structure of aspect 11, wherein at least one of the interface layers has a thickness that is different than that of at least one other interface layer.

Aspect 13. The structure of any one of aspects 11 to 12, wherein each of the interface layers has the same thickness.

Aspect 14. The structure of any one of aspects 11 to 13, wherein at least one of the interface layers has a bandgap that is constant across the thickness of the interface layer.

Aspect 15. The structure of any one of aspects 11 to 14, wherein at least one of the interface layers has a bandgap that varies linearly across the thickness of the interface layer.

Aspect 16. The structure of any one of aspects 11 to 15, wherein at least one of the interface layers has a bandgap that varies non-linearly across the thickness of the interface layer.

Aspect 17. The structure of any one of aspects 11 to 16, wherein at least one of the interface layers is intentionally doped in at least a portion of the interface layer.

Aspect 18. The structure of any one of aspects 11 to 17, wherein at least one of the interface layers has a composition that is different than the composition of the active region.

Aspect 19. The structure of any one of aspects 11 to 18, wherein at least one of the interface layers has a composition that is different than another interface layer.

Aspect 20. The structure of any one of aspects 11 to 18, wherein each of the interface layers has the same composition.

Aspect 21. The structure of any one of aspects 11 to 20, wherein at least one of the interface layers has a non-uniform bandgap.

Aspect 22. The structure of any one of aspects 11 to 21, wherein each of the interface layers independently comprises a uniform bandgap across the thickness of the interface layer or a non-uniform bandgap across the thickness of the interface layer.

Aspect 23. The structure of any one of aspects 11 to 22, wherein each of the interface layers independently comprises GaInNAs, GaNAsSb, GaInNAsSb, GaInNAsBi, GaNAsSbBi, GaNAsBi, GaInNAsSbBi, or a combination of any of the foregoing.

Aspect 24. The structure of any one of aspects 1 to 10, wherein the first interface region comprises two or more stepped interface layers.

Aspect 25. The structure of any one of aspects 1 to 10, wherein the second interface region comprises two or more stepped interface layers.

Aspect 26. The structure of any one of aspects 1 to 10, wherein the first interface region comprises one or more graded interface layers.

Aspect 27. The structure of any one of aspects 1 to 10, wherein the second interface region comprises one or more graded interface layers.

Aspect 28. The structure of any one of aspects 2 to 16, wherein the dilute nitride material comprises GaInNAs, GaNAsSb, GaInNAsSb, GaInNAsBi, GaNAsSbBi, GaNAsBi, GaInNAsSbBi, or a combination of any of the foregoing.

### Examples

The following examples describe in detail examples of compounds, devices and methods provided by the present disclosure. It will be apparent to those skilled in the art that many modifications, both to materials and methods, may be practiced without departing from the scope of the disclosure.

Superlattice Graded Interface Layer

A Ga₁₋ₓInₓN_{y}As_{1-y-z} Sb_{z} optical absorber material with a fixed bandgap in which 0.16≤x≤0.24, 0.04≤y≤0.055, and 0≤z≤0.04 can be designed to have a bandgap of about 0.85 eV, measured at room temperature, and can be placed between a n+ doped GaAs layer and a p+ doped GaAs layer, GaAs having a bandgap, measured at room temperature, of about 1.42 eV. The band offset in the conduction band is larger than the band offset in the valence band. To decrease the conduction band barrier, a graded interface layer can be included between the Ga₁₋ₓInₓN_{y}As_{1-y-z} Sb_{z} and the n+ GaAs layer. The graded interface may be formed using a superlattice of (undoped/doped??) GaAs and Ga₁₋ₓInₓN_{y}As_{1-y-z} Sb_{z}, with varying layer thicknesses across the superlattice providing an average composition change from Ga₁₋ₓInₓN_{y}As_{1-y-z}Sb_{z} to GaAs. In order to transition the bandgap from Ga₁₋ₓInₓN_{y}As_{1-y-z} Sb_{z} to GaAs, reducing the barrier height, the graded composition can be provided using adjacent layers of GaAs/Ga₁₋ₓInₓN_{y}As_{1-y-z}Sb_{z} grown using a suitable growth rate, for example such as less than 1.5 μm/hr or less than 1 μm/hr or less than 0.5 μm/hr. that allows a structure with 1/5 monolayers, 2/4 monolayers, 3/3 monolayers, 4/2 monolayers and 5/1 monolayers to be grown, each layer pairing having a thickness of about 1.7 nm, with a successively increasing average bandgap, providing a graded interface region approximately 8.5 nm thick, or a structure with 2/10 monolayers, 4/8 monolayers, 6/6 monolayers, 8/4 monolayers and 10/2 monolayers, each layer pairing having a thickness of about 3.4 nm, with a successively increasing average bandgap, providing a graded interface region approximately 17 nm thick.

To fabricate optoelectronic devices provided by the present disclosure, a plurality of layers can be deposited on a substrate in a materials deposition chamber. The plurality of layers may include active regions, doped regions, contact layers, etch stop layers, release layers (i.e., layers designed to release the semiconductor layers from the substrate when a specific process sequence, such as chemical etching, is applied), buffer layers, or other semiconductor layers.

The plurality of layers can be deposited, for example, by molecular beam epitaxy (MBE) or by metal-organic chemical vapor deposition (MOCVD). Combinations of deposition methods may also be used.

A semiconductor optoelectronic device can be subjected to one or more thermal annealing treatments after growth. For example, a thermal annealing treatment can include the application of a temperature of 400° C. to 1,000° C. for from 10 seconds to 10 hours. Thermal annealing may be performed in an atmosphere that includes air, nitrogen, arsenic, arsine, phosphorus, phosphine, hydrogen, forming gas, oxygen, helium and any combination of the preceding materials.

Devices provided by the present disclosure can comprise a GaInNAsSb active region overlying a GaAs substrate. The GaInNAsSb layer can be compressively strained with respect to the GaAs substrate. For example, the XRD peak slitting between the GaInNAsSb peak and the GaAs substrate peak can be, for example, from 300 arcsecs to 1,000 arcsecs, from 600 arcsecs to 800 arcsecs, or from 650 arcsecs to 750 arcsecs. An XRD splitting from 600 arcsecs to 1,000 arcsecs, corresponds to a compressive strain from 0.2% to 0.35%.

A dilute nitride layer or dilute-nitride active region such as a GaInNAsSb active layer or GaInNAsSb active region can have an intrinsic or unintentional doping equivalent to a doping concentration, for example, less than 1×10¹⁶ cm⁻³, less than 5×10¹⁵ cm⁻³, or less than 1×10¹⁵ cm⁻³, measured at room temperature (25° C.). A dilute nitride active layer or dilute nitride active region such as a GaInNAsSb active layer or GaInNAsSb active region can have an intrinsic or unintentional doping equivalent to a doping concentration, for example, from 0.5×10¹⁴ cm⁻³ to 1×1016 cm⁻³ or from 1×10¹⁵ cm⁻³ to 5×10¹⁵ cm⁻³, measured at room temperature (25° C.).

A dilute nitride active layer or dilute nitride active region such as a GaInNAsSb active layer or GaInNAsSb active region can have a minority carrier lifetime, for example, from 1.0 ns to 3.0 ns, from 1.5 ns to 2.5 ns, or from 1.5 ns to 2.0 ns. A dilute nitride active layer or dilute nitride active region such as a GaInNAsSb active layer or GaInNAsSb active region can have a minority carrier lifetime, for example, greater than 1.0 ns, greater than 1.5 ns, greater than 2.0 ns, or greater than 2.5 ns. The TRPL kinetics are measured at room temperature (approximately 25° C.), using an excitation wavelength of 970 nm, with an average CW power of 0.250 mW, and a pulse duration of 200 fs generated by a Ti:Sapphire:OPA laser with a pulse repetition rate of 250 kHz and a laser beam diameter at the sample of 1 mm.

A dilute nitride active layer or dilute nitride active region such as a GaInNAsSb active layer or GaInNAsSb active region can have a bandgap, for example, from 0.9 eV to 0.92 eV.

A dilute nitride active layer or dilute nitride active region such as a GaInNAsSb active layer or GaInNAsSb active region can have photoluminescence spectrum having a FWHM, for example, from 50 nm to 150 nm, from 50 nm to 125 nm, from 50 nm to 70 nm, or from 75 nm to 125 nm, as determined by photoluminescence spectroscopy.

The dilute nitride active layer or dilute nitride active region such as a GaInNAsSb active layer or GaInNAsSb active region can have a thickness, for example, from 0.25 μm to 2.5 μm, from 0.5 μm to 2.0 μm, or from 0.5 μm to 1.5 μm.

A device provided by the present disclosure, such as a photodetector, can have the structure of FIG. 15A, 15B or 15C.

A device such as a photodetector provided by the present disclosure can have a diameter, for example, from 20 μm to 3 mm, from 0.5 mm to 2.5 mm, or from 1 mm to 2 mm, where diameter refers to the in-plane width of the active region of the device. For example, referring to FIG. 15 the diameter refers to the distance between contacts 1512. A device such as a photodetector can have a diameter, for example, greater than 20 μm, greater than 100 μm, greater than 500 μm, greater than 1 mm, or greater than 2 mm, where diameter refers to the in-plane width of the active region of the device.

A device such as a photodetector provided by the present disclosure can have sidewall angles between about 700 and 900 (perpendicular to the substrate) such as between about 800 and 90°, where the sidewall angles refer to the angles of the sidewalls of the stacked epitaxial layers with respect to the plane of the surface of the substrate.

A photodetector provided by the present disclosure having a dilute nitride active region can have the structure shown in FIG. 15A, 15B or 15C. The substrate can be a semi-insulating GaAs substrate, the first barrier layer can be a p-doped GaAs layer having a thickness from 0.05 μm to 0.15 μm and a doping level from 1×10¹⁷ cm⁻³ to 1×10¹⁹ cm⁻³, the second barrier layer can be an n-doped GaAs layer having a thickness from 0.05 μm to 0.15 μm and a doping level from 1×10¹⁷ cm⁻³ to 1×10¹⁹ cm⁻³, and the active region can comprise a GaInNAsSb material with a thickness from about 0.5 μm to 2.5 μm and with an XRD splitting between the GaInNAsSb peak and the GaAs substrate from about 300 arcsecs to 1000 arcsecs. The interface layer(s) can comprise a GaInNAsSb material with a thickness less than 100 nm or less than 20 nm or less than 10 nm. The interface layer(s) may be undoped (with only unintentional doping levels less than about 1×10¹⁶ cm⁻³) or may be doped with a doping level from 1×10¹⁷ cm⁻³ to 1×10¹⁹ cm⁻³, over at least a portion of the thickness of the interface layer(s).

Finally, it should be noted that there are alternative ways of implementing the embodiments disclosed herein. Accordingly, the present embodiments are to be considered as illustrative and not restrictive. Furthermore, the claims are not to be limited to the details given herein and are entitled their full scope and equivalents thereof.

1. A compound semiconductor optoelectronic structure, comprising:
a substrate having a substrate surface;
a first doped region overlying the substrate surface, wherein the first doped region has a first doped region bandgap;
an active region overlying the first doped region, wherein the active region comprises a dilute nitride material having a dilute nitride material bandgap; and
a second doped region overlying the active region, wherein the second doped region has a second doped region bandgap; and
a first interface region or a second interface region adjacent to the active region and to the first doped region,
wherein the first interface region has a first interface region bandgap, the first interface region bandgap is between the dilute nitride material bandgap and the first doped region bandgap; and
wherein the second interface region has a second interface region bandgap, the second interface region bandgap is between the dilute nitride material bandgap and the second doped region bandgap.

2. The compound semiconductor optoelectronic structure of claim 1, wherein compound semiconductor optoelectronic structure comprises the first interface region adjacent to the active region, the first interface region further adjacent to the first doped region.

3. The compound semiconductor optoelectronic structure of claim 1, wherein the structure comprises the second interface region adjacent the active region, the second interface region adjacent to the second doped region.

4. The compound semiconductor optoelectronic structure of claim 1, wherein the structure comprises:
the first interface region adjacent to the active region and the first doped region; and
the second interface region adjacent the active region and the second doped region

5. The compound semiconductor optoelectronic structure of claim 1, wherein the first interface region or the second interface region comprises a dilute nitride material.

6. The compound semiconductor optoelectronic structure of claim 1, wherein the first interface region or the second interface region has a thickness less than 100 nm.

7. The compound semiconductor optoelectronic structure of claim 1, wherein,
the first interface region comprises one or more interface layers; or
the second interface region comprises one or more interface layers; or
each of the first interface region and the second interface region independently comprises one or more interface layers.

8. The compound semiconductor optoelectronic structure of claim 7, wherein at least one of the interface layers has a thickness that is different than a thickness of at least one other interface layer.

9. The compound semiconductor optoelectronic structure of claim 7, wherein each of the interface layers has the same thickness.

10. The compound semiconductor optoelectronic structure of claim 7, wherein at least one of the interface layers has a bandgap that is constant across a thickness of the at least one of the interface layers.

11. The compound semiconductor optoelectronic structure of claim 7, wherein at least one of the interface layers has a bandgap that varies linearly across a thickness of the at least one of the interface layers.

12. The compound semiconductor optoelectronic structure of claim 7, wherein at least one of the interface layers has a bandgap that varies non-linearly across a thickness of the at least one of the interface layers.

13. The compound semiconductor optoelectronic structure of claim 7, wherein at least one of the interface layers is intentionally doped in at least a portion of the at least one of the interface layers.

14. The compound semiconductor optoelectronic structure of claim 7, wherein at least one of the interface layers has a composition that is different than the composition of the active region.

15. The compound semiconductor optoelectronic structure of claim 7, wherein each of the interface layers has the same composition.

16. The compound semiconductor optoelectronic structure of claim 7, wherein at least one of the interface layers has a non-uniform bandgap.

17. The compound semiconductor optoelectronic structure of claim 7, wherein each of the interface layers independently comprises a uniform bandgap across the thickness of the interface layer or a non-uniform bandgap across the thickness of the interface layer.

18. The compound semiconductor optoelectronic structure of claim 7, wherein the interface layers and the dilute nitride material comprises GaInNAs, GaNAsSb, GaInNAsSb, GaInNAsBi, GaNAsSbBi, GaNAsBi, GaInNAsSbBi, or a combination of any of the foregoing.

19. The compound semiconductor optoelectronic structure of claim 1, wherein the first interface region or the second interface region comprises two or more stepped interface layers.

20. The compound semiconductor optoelectronic structure of claim 1, wherein the first interface region or the second interface region comprises one or more graded interface layers.
